(19) United States
(12) Patent Application Publication
(10) Pub. No.: US 2025/0212547 A1
(43) Pub. Date: Jun. 26, 2025

(54) MODULE AND ELECTRONIC EQUIPMENT

(71) Applicant: CANON KABUSHIKI KAISHA, Tokyo (JP)

(72) Inventors: YOSHITOMO FUJISAWA, Kanagawa (JP); RYO FUJIYAMA, Kanagawa (JP); YUSUKE HORIUCHI, Kanagawa (JP); HIDETO TAKAHASHI, Tokyo (JP)

(21) Appl. No.: 18/977,994

(22) Filed: Dec. 12, 2024

(30) Foreign Application Priority Data
Dec. 26, 2023 (JP) 2023-219758
Apr. 24, 2024 (JP) 2024-070731

(51) Int. Cl. H10F 39/00

(52) U.S. Cl. CPC H10F 39/811; H10F 39/804

(57) ABSTRACT

A module includes a first printed wiring board; a second printed wiring board arranged on a main surface of the first printed wiring board and joined to the first printed wiring board by first solder joints; a third printed wiring board arranged on a side opposite to a side on which the first printed wiring board is arranged with respect to the second printed wiring board and joined to the second printed wiring board by second solder joints; and first and second reinforcing resin portions, wherein the second printed wiring board has first and second side surfaces opposing each other in a first direction, the first reinforcing resin portion adheres to the main surface, the first side surface, and the third printed wiring board, and is away from one end of the first side surface of the second printed wiring board in the second direction.

### BACKGROUND

### Field of the Invention

The present disclosure relates to a module and electronic equipment.

### Description of the Related Art

In electronic equipment, communication speed and mounting density of semiconductor devices are advancing, and three-dimensional mounting technology in which a plurality of semiconductor devices and printed circuit boards are stacked and mounted is essential. Semiconductor devices are semiconductor packages that have semiconductor elements and interposers, and are digital signal processors and memories, for example. The printed circuit board serves to electrically connect a plurality of semiconductor devices, for example, when they are stacked.

In recent years, semiconductor devices equipped in electronic devices, such as mobile devices and the like, have been experiencing a large temperature rise during operation due to high-speed and large-capacity data processing. In such semiconductor devices, the stress on the solder joints is also increasing due to thermal deformation. In particular, in a three-dimensional mounting structure in which semiconductor devices and printed circuit boards with different linear expansion coefficients are stacked on a printed wiring board, the risk of deterioration in the reliability of the solder joints may increase.

Therefore, Japanese Patent Application Laid-Open No. 2015-50355 discloses a mounting method in which the stress applied to the solder joints are reduced and the reliability of the solder joints are improved by forming reinforcing resin portions at the peripheral edges of the four corners of a semiconductor device and a printed circuit board to suppress thermal deformation of each of them. Specifically, the mounting method described in Japanese Patent Application Laid-Open No. 2015-50355 is a mounting method of a three-dimensional mounting structure in which a semiconductor device is mounted on a printed wiring board, resin is applied on the printed wiring board in the vicinity of the semiconductor device, and a printed circuit board is mounted on the semiconductor device and reflow heating is performed. According to the above method, the resin is cured at the same time as the solder joints are made by the reflow process, and the solder joints can be reinforced.

However, depending on the three-dimensional mounting structure, even if the resin is formed in a U-shape disclosed in Japanese Patent Application Laid-Open No. 2015-50355, stress can be concentrated in the solder joints in the vicinity of the portion where no resin is formed. Therefore, in the mounting structure according to the mounting method disclosed in Japanese Patent Application Laid-Open No. 2015-50355, a sufficient reinforcing effect cannot be obtained, and the reliability of the solder joint is insufficient.

### SUMMARY

It is an object of the present disclosure to provide a module that can improve the reliability of a solder joint.

According to one aspect of the present disclosure, there is provided a module including: a first printed wiring board; a second printed wiring board arranged on a main surface of the first printed wiring board and joined to the first printed wiring board by a plurality of first solder joints; a third printed wiring board arranged on a side opposite to a side on which the first printed wiring board is arranged with respect to the second printed wiring board and joined to the second printed wiring board by a plurality of second solder joints; a first reinforcing resin portion; and a second reinforcing resin portion, wherein the second printed wiring board has a first side surface and a second side surface opposing each other in a first direction, and has a third surface and a fourth side surface opposing each other in a second direction that intersects the first direction, wherein the first reinforcing resin portion adheres to the main surface of the first printed wiring board, the first side surface of the second printed wiring board, and the third printed wiring board, and is away from at least one end of both ends of the first side surface of the second printed wiring board in the second direction, and wherein the second reinforcing resin portion adheres to the main surface of the first printed wiring board, the second side surface of the second printed wiring board, and the third printed wiring board, and is away from at least one end of both ends of the second side surface of the second printed wiring board in the second direction.

According to another aspect of the present disclosure, there is provided a module including: a first printed wiring board; a second printed wiring board arranged on a main surface of the first printed wiring board and joined to the first printed wiring board by a plurality of first solder joints; a third printed wiring board arranged on a side opposite to a side on which the first printed wiring board is arranged with respect to the second printed wiring board and joined to the second printed wiring board by a plurality of second solder joints; a first reinforcing resin portion; and a second reinforcing resin portion, wherein the second printed wiring board has a first side surface and a second side surface opposing each other in a first direction, and has a third side surface and a fourth side surface opposing each other in a second direction that intersects the first direction, and wherein the first reinforcing resin portion adheres to a main surface of the first printed wiring board, the first side surface of the second printed wiring board, and the third printed wiring board, is separated from a solder joint closest to the first reinforcing resin portion among one joint group of the plurality of first solder joints and the plurality of second solder joints, and adheres to a solder joint closest to the first reinforcing resin portion among another joint group of the plurality of first solder joints and the plurality of second solder joints.

Further features of the present disclosure will become apparent from the following description of exemplary embodiments with reference to the attached drawings.

### BRIEF DESCRIPTION OF THE DRAWINGS

FIG. 1 is a schematic diagram illustrating an example of electronic equipment according to a first embodiment.

FIG. 2 is a perspective view illustrating a three-dimensional mounting structure according to the first embodiment.

FIG. 3 is a cross-sectional view illustrating a three-dimensional mounting structure according to the first embodiment.

FIG. 4A is a top view illustrating an interposer in the three-dimensional mounting structure according to the first embodiment.

FIG. 4B is a top view illustrating a printed circuit board in the three-dimensional mounting structure according to the first embodiment.

FIG. 4C is a top view illustrating the three-dimensional mounting structure according to the first embodiment.

FIG. 5A is a cross-sectional view illustrating the three-dimensional mounting structure according to the first embodiment.

FIG. 5B is a cross-sectional view illustrating the three-dimensional mounting structure according to the first embodiment.

FIG. 5C is a cross-sectional view illustrating the three-dimensional mounting structure according to the first embodiment.

FIG. 5D is a side view illustrating the three-dimensional mounting structure according to the first embodiment.

FIG. 5E is a cross-sectional view illustrating the three-dimensional mounting structure according to the first embodiment.

FIG. 6A is a cross-sectional view illustrating a three-dimensional mounting structure according to a second embodiment.

FIG. 6B is a cross-sectional view illustrating the three-dimensional mounting structure according to the second embodiment.

FIG. 6C is a cross-sectional view illustrating the three-dimensional mounting structure according to the second embodiment.

FIG. 7A is a cross-sectional view illustrating a three-dimensional mounting structure according to a third embodiment.

FIG. 7B is a cross-sectional view illustrating the three-dimensional mounting structure according to the third embodiment.

FIG. 8A is a cross-sectional view illustrating a three-dimensional mounting structure according to a fourth embodiment.

FIG. 8B is a cross-sectional view illustrating the three-dimensional mounting structure according to the fourth embodiment.

FIG. 9A is a top view illustrating a three-dimensional mounting structure according to a fifth embodiment.

FIG. 9B is a side view illustrating the three-dimensional mounting structure according to the fifth embodiment.

FIG. 10A is a top view illustrating a three-dimensional mounting structure according to a sixth embodiment.

FIG. 10B is a side view illustrating the three-dimensional mounting structure according to the sixth embodiment.

FIG. 10C is a plan view illustrating a solder joint in the three-dimensional mounting structure according to the sixth embodiment.

FIG. 10D is a plan view illustrating the solder joint in the three-dimensional mounting structure according to the sixth embodiment.

FIG. 11A is a graph showing a relationship between the coating length of a resin and the stress applied to the solder joint.

FIG. 11B is a graph illustrating a relationship between the coating length of the resin and the reliability of the solder joint.

FIG. 12A is a top view illustrating a three-dimensional mounting structure according to another embodiment.

FIG. 12B is a side view illustrating the three-dimensional mounting structure according to another embodiment.

FIG. 12C is a cross-sectional view illustrating the three-dimensional mounting structure according to another embodiment.

### DESCRIPTION OF THE EMBODIMENTS

### First Embodiment

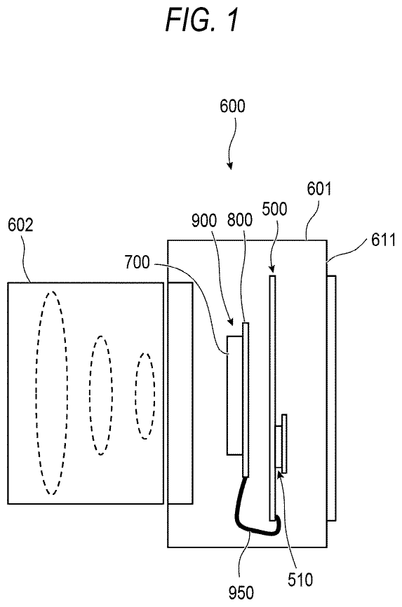

A three-dimensional mounting structure which is a module according to a first embodiment of the present disclosure and electronic equipment using the three-dimensional mounting structure will be described with reference to FIG. 1 to FIG. 5E.

First, an example of electronic equipment using the three-dimensional mounting structure according to the present embodiment will be described with reference to FIG. 1. FIG. 1 is a schematic diagram illustrating a digital camera 600 with an interchangeable lens, which is an example of the electronic equipment using the three-dimensional mounting structure 500 according to the present embodiment. Note that, although the digital camera 600 with an interchangeable lens will be described in the present embodiment, the digital camera 600 may be a lens-integrated type camera in which a lens is built in a camera body 601. The electronic equipment in which the three-dimensional mounting structure 500 according to the present embodiment is used is not limited to the digital camera 600, which is an imaging apparatus, but may be any kind of equipment.

As illustrated in FIG. 1, the digital camera 600 is a lens-interchangeable digital camera such as a digital single-lens reflex camera, a digital mirrorless camera, or the like, for example, and includes a camera body 601 and a lens unit 602 including lenses. The lens unit 602 is detachably attached to the camera body 601.

The camera body 601 includes a housing 611, a three-dimensional mounting structure 500, and a sensor module 900. The three-dimensional mounting structure 500 and the sensor module 900 are processing modules, respectively, and are arranged inside the housing 611. The three-dimensional mounting structure 500 and the sensor module 900 are electrically connected to each other by a flexible wiring 950. The flexible wiring 950 is, for example, a flexible cable, a flexible wiring board, or the like.

The sensor module 900 includes an image sensor 700, which is an imaging element and a printed circuit board 800. The image sensor 700 is mounted on the printed circuit board 800. The image sensor 700 is, for example, a complementary metal oxide semiconductor (CMOS) image sensor or a charge coupled device (CCD) image sensor. The image sensor 700 has a function of converting light incident through the lens unit 602 into an electrical signal.

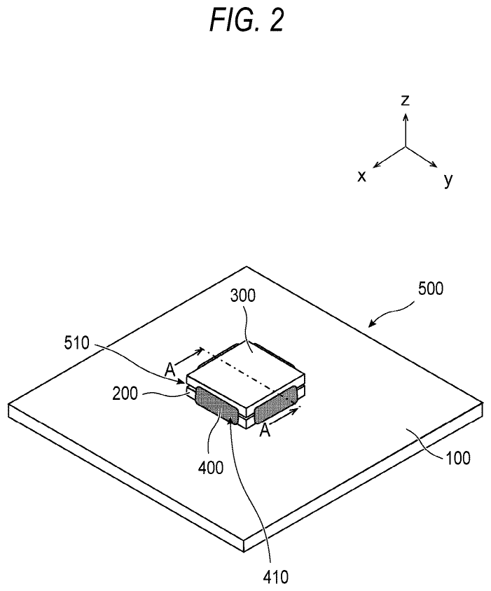

Next, the configuration of the three-dimensional mounting structure 500 according to the present embodiment will be described with reference to FIG. 2. FIG. 2 is a perspective view illustrating the three-dimensional mounting structure 500 according to the present embodiment. In the following description, as illustrated in FIG. 2, among the surface directions of a printed circuit board 100 described below, a direction parallel to one longitudinal direction of a reinforcing resin portion 410 described below is set to an x-axis direction, and a direction orthogonal to the x-axis direction in the surface direction is set to a y-axis direction. A direction orthogonal to the x-axis direction and the y-axis direction is set to a z-axis direction. The x-axis direction, the y-axis direction and the z-axis direction do not necessarily have to be orthogonal to each other, but only cross each other.

As illustrated in FIG. 2, the three-dimensional mounting structure 500 includes a mounting structure 510, a printed circuit board 100, and a reinforcing resin portion 410. The mounting structure 510 includes a semiconductor device 200. The reinforcing resin portion 410 is composed of a resin 400. The mounting structure 510 is mounted on one main surface of the printed circuit board 100 as a mounting surface. The printed circuit board 100 is, for example, a rigid board with components mounted on a printed wiring board.

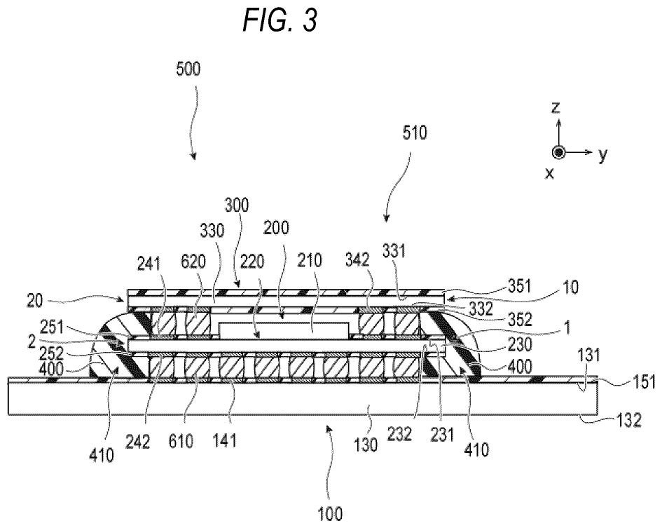

The mounting structure 510 includes, for example, the semiconductor device 200 and a printed circuit board 300, and is a structure in which the printed circuit board 300 is mounted and stacked on the semiconductor device 200 via a solder joint 620 (see FIG. 3). The semiconductor device 200 is, for example, a digital signal processor and has a function of acquiring an electric signal from the image sensor 700, correcting the acquired electric signal, and generating image data. The printed circuit board 300 is, for example, a rigid board on which components are mounted on a printed wiring board. The reinforcing resin portion 410 is composed of the resin 400, and fixes the printed circuit board 100 and the mounting structure 510.

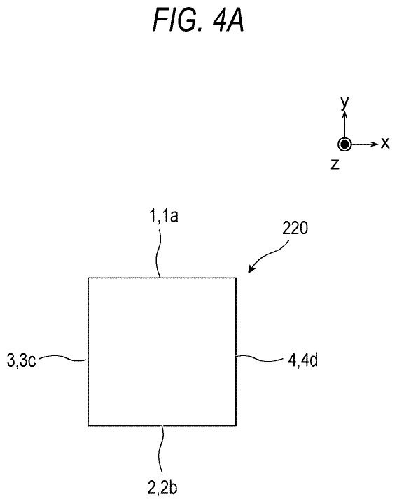

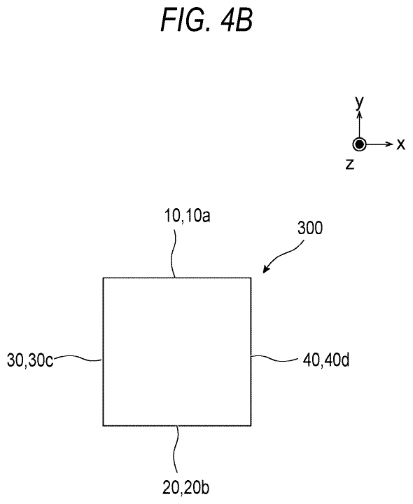

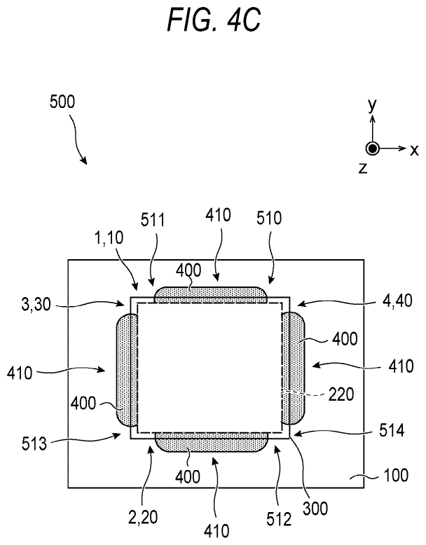

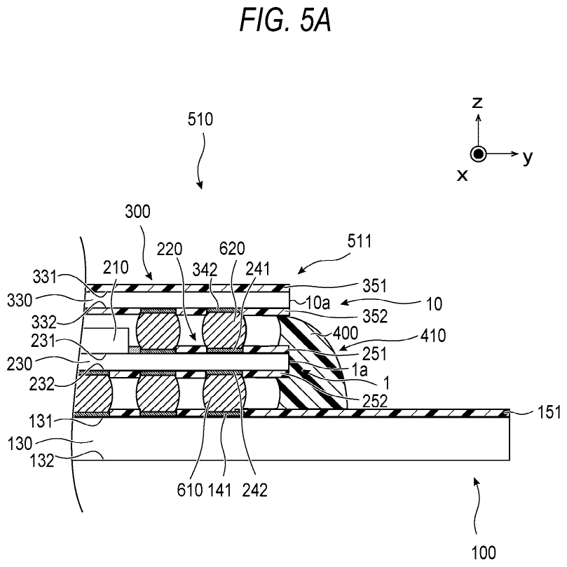

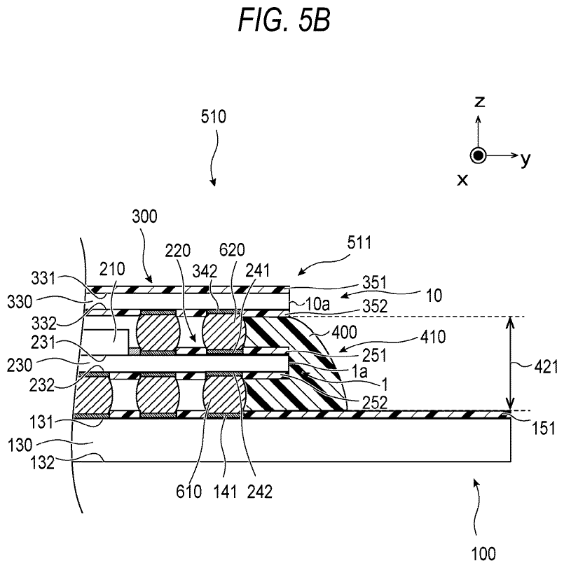

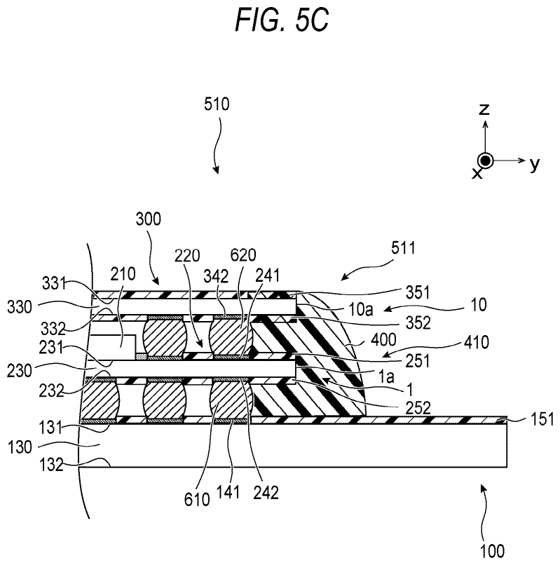

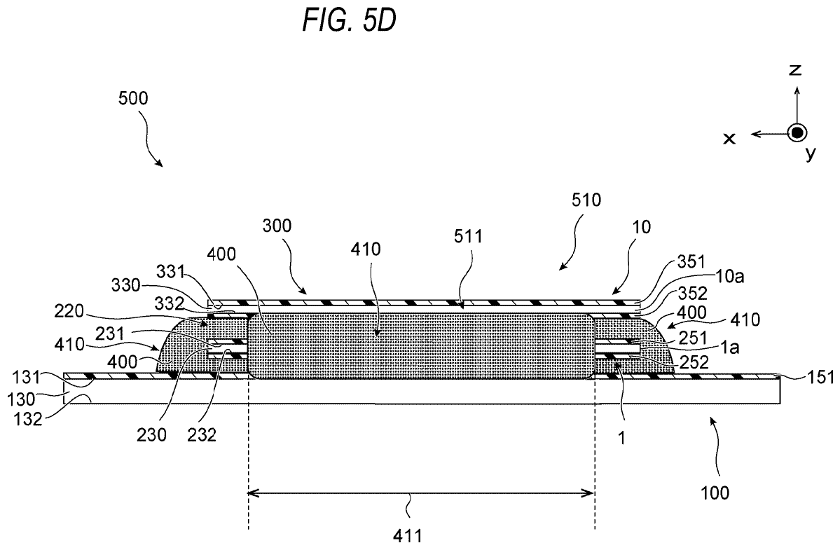

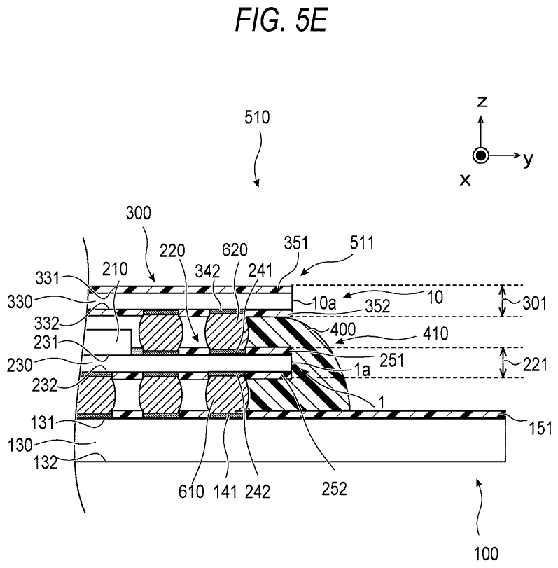

Next, the specific structure of the three-dimensional mounting structure 500 according to the present embodiment will be described with reference to FIG. 3 to FIG. 5E. FIG. 3 is a cross-sectional view illustrating a cross section of the three-dimensional mounting structure 500 along a line A-A illustrated in FIG. 2. FIG. 4A to FIG. 4C are top views illustrating an interposer 220 of the semiconductor device 200, the printed circuit board 300 and the three-dimensional mounting structure 500, respectively. FIG. 4A to FIG. 4C are top views viewed in the z-axis direction, respectively. FIG. 5A to FIG. 5C and FIG. 5E are enlarged views illustrating cross sections of the three-dimensional mounting structure 500 along the line A-A illustrated in FIG. 2. FIG. 5D is a side view illustrating the three-dimensional mounting structure 500. FIG. 5D is a side view viewed in the y-axis direction.

The semiconductor device 200 is, for example, a semiconductor package of an area array, specifically, a semiconductor package of a BGA (Ball Grid Array). As illustrated in FIG. 3, the semiconductor device 200 includes a semiconductor element 210 and an interposer 220. The interposer 220 is a printed circuit board which is a rigid board, for example, in which components are mounted on a printed circuit board. The semiconductor element 210 is mounted on the interposer 220.

As illustrated in FIG. 4A, the interposer 220 has a rectangular planar shape in the top view viewed in the z-axis direction, and has side surfaces 1a, 2b, 3c, and 4d on sides 1, 2, 3, and 4 in the rectangular planar shape, respectively. The sides 1 and 2 are two opposite sides, and the sides 3 and 4 are two opposite sides. In the rectangular planar shape including the sides 1, 2, 3 and 4 of the interposer 220, the length of the long side is not particularly limited, but is, for example, 1.05 times or more or 1 mm or more larger than the length of the short side. The side surfaces 1a and 2b are edge surfaces of the interposer 220 opposing each other in the y-axis direction. The side surfaces 3c and 4d are edge surfaces of the interposer 220 opposing each other in the x-axis direction. For example, the distance between the side surface 1a and the side surface 2b is smaller than the distance between the side surface 3c and the side surface 4d. That is, among the sides 1, 2, 3 and 4 of the interposer 220, the sides 1 and 2 may be the long sides and the sides 3 and 4 may be the short sides. The distance between the side surface la and the side surface 2b, that is, the length of the side surface 3c and the side surface 4d in the y-axis direction may be, for example, 5 to 50 mm, typically 10 to 30 mm, and preferably 10 to 20 mm. The distance between the side surface 3c and the side surface 4d, that is, the length of the side surface 1a and the side surface 2b in the x-axis direction may be, for example, 5 to 50 mm, typically 10 to 30 mm, and preferably 10 to 20 mm. It is effective to provide the reinforcing resin portion 410 on the longer sides (the sides 1 and 2) than on the shorter sides (thew sides 3 and 4).

The interposer 220 includes an insulating substrate 230 as illustrated in FIG. 3. The insulating substrate 230 has a main surface 231 and a main surface 232 on the opposite side to the main surface 231. The main surface 231 is a surface on which the semiconductor element 210 is mounted (die-bonded) and is a surface opposite to the printed circuit board 100. The main surface 232 is a surface on the side of the printed circuit board 100. The material of the insulating substrate 230 is, for example, glass epoxy. The semiconductor element 210 is made of, for example, silicon. Note that the semiconductor element 210 may be arranged between the interposer 220 and the printed circuit board 300, and may be mounted (die-bonded) on the main surface 332 of the printed circuit board 300 on the side of the interposer 220, for example.

The interposer 220 includes a plurality of lands 241 arranged on the main surface 231 of the insulating substrate 230, and a plurality of lands 242 arranged on the main surface 232. The plurality of lands 241 are arranged on the main surface 231 in a peripheral arrangement pattern surrounding the outer periphery of the semiconductor element 210, for example. The plurality of lands 242 may be arranged on the main surface 232 in a grid arrangement pattern, that is, in a matrix arrangement pattern, or may be arranged on the main surface 232 in a staggered arrangement pattern. The lands 241 and 242 are terminals formed of a conductive metal material such as copper or gold, for example.

The interposer 220 includes solder resists 251 and 252. That is, the solder resist 251 is provided on the main surface 231 of the insulating substrate 230. The solder resist 251 is a film made of a solder resist material. Each of the plurality of lands 241 is exposed by an opening formed in the solder resist 251. The solder resist 252 is provided on the main surface 232 of the insulating substrate 230. The solder resist 252 is a film made of a solder resist material. Each of the plurality of lands 242 is exposed by an opening formed in the solder resist 252. The lands 241 and 242 may be either SMD (Solder Mask Defined) or NSMD (Non-Solder Mask Defined) lands.

As illustrated in FIG. 4B, the printed circuit board 300 has a rectangular planar shape in the top view viewed in the z-axis direction, and has side surfaces 10a, 20b, 30c, and 40d at the sides 10, 20, 30, and 40 of the rectangular planar shape, respectively. The sides 10 and 20 are two opposite sides each other, and the sides 30 and 40 are two opposite sides each other. The sides 10, 20, 30, and 40 are respectively located at the same sides of the mounting structure 510 as the sides 1, 2, 3, and 4 of the interposer 220. In the rectangular planar shape including the sides 10, 20, 30, and 40 of the printed circuit board 300, the length of the long side is, for example, 1.2 to 1.6 times the length of the short side, although not particularly limited. The length of the long side of the rectangular planar shape including the sides 10, 20, 30, and 40 is not particularly limited, but is 1.1 to 1.5 times the length of the side in the same direction of the rectangular planar shape including the sides 1, 2, 3, and 4 of the interposer 220, for example. The side surfaces 10a and 20b are edge surfaces of the printed circuit board 300 opposite each other in the y-axis direction. The side surfaces 30c and 40d are edge surfaces of the printed circuit board 300 opposite each other in the x-axis direction.

For example, in the printed circuit board 300, the distance between the side surface 30c and the side surface 40d is larger than the distance between the side surface 10a and the side surface 20b. For example, the distance between the side surface 30c and the side surface 40d in the printed circuit board 300 is larger than the distance between the side surface 3c and the side surface 4d in the interposer 220.

The printed circuit board 300 includes an insulating substrate 330 as illustrated in FIG. 3. The insulating substrate 330 has a main surface 331 and a main surface 332 opposite to the main surface 331. The main surface 331 is a surface opposite to the interposer 220 and facing outward. The main surface 332 is a surface on the side of the interposer 220. The insulating substrate 330 is made of, for example, glass epoxy.

The printed circuit board 300 includes a plurality of lands 342 arranged on the main surface 332 of the insulating substrate 330. The plurality of lands 342 are arranged on the main surface 332 in an arrangement pattern corresponding to the arrangement pattern of the plurality of lands 241 in the interposer 220. The lands 342 are terminals formed of a conductive metal material such as copper or gold, for example.

The printed circuit board 300 includes solder resists 351 and 352. That is, the solder resist 351 is provided on the main surface 331 of the insulating substrate 330. The solder resist 352 is provided on the main surface 332 of the insulating substrate 330. The solder resists 351 and 352 are films made of a solder resist material. Each of the plurality of lands 342 is exposed by an opening formed in the solder resist 352. The lands 342 may be either SMD or NSMD lands.

The printed circuit board 100 includes an insulating substrate 130 as illustrated in FIG. 3. The insulating substrate 130 has a main surface 131 on the side on which the mounting structure 510 is mounted and a main surface 132 on the side opposite to the main surface 131 and facing outward. The insulating substrate 330 is made of, for example, glass epoxy.

The printed circuit board 100 includes a plurality of lands 141 arranged on the main surface 131 of the insulating substrate 130. The plurality of lands 141 are arranged on the main surface 131 in an arrangement pattern corresponding to the arrangement pattern of the plurality of lands 242 in the interposer 220. The land 141 is a terminal formed of a conductive metal material such as copper or gold, for example.

The printed circuit board 100 includes a solder resist 151. That is, the solder resist 151 is provided on the main surface 131 of the insulating substrate 130. The solder resist 151 is a film made of a solder resist material. Each of the plurality of lands 141 is exposed by an opening formed in the solder resist 151. The lands 141 may be either SMD or NSMD lands.

The plurality of lands 141 and the plurality of lands 242 are joined by solder joint 610 formed of solder. The plurality of lands 241 and the plurality of lands 342 are joined by solder joints 620 formed of solder. The solder forming the solder joints 610 and 620 is, for example, a solder ball. The arrangement of the solder joints 610 and the arrangement of the solder joints 620 need not be aligned vertically when viewed from the x-axis direction and the y-axis direction.

Thus, the interposer 220 is arranged on one surface of the printed circuit board 100 and is joined to the printed circuit board 100 by the plurality of solder joints 610. The printed circuit board 300 is arranged on the side opposite to the side on which the printed circuit board 100 is arranged with respect to the interposer 220 and is joined to the interposer 220 by the plurality of solder joints 620. The plurality of solder joints 610 are provided at least on the sides 1, 2, 3, and 4 of the interposer 220. The plurality of solder joints 620 are also provided at least on the sides 1, 2, 3, and 4 of the interposer 220. The plurality of solder joints 620 are arranged around the semiconductor element 210 on the surface of the interposer 220 on the side of the printed circuit board 300.

As illustrated in FIG. 4C, the interposer 220 and the printed circuit board 300 fixed to each other by the solder joints 620 are arranged so that the interposer 220 and the printed circuit board 300 overlap each other to make the printed circuit board 300 cover the interposer 220 in the top view viewed in the z-axis direction. In the top view, the sides 10, 20, 30, and 40 in the rectangular shape of the printed circuit board 300 are respectively located on the same sides of the mounting structure 510 as the sides 1, 2, 3, and 4 in the rectangular shape of the interposer 220. The rectangular shape of the interposer 220 may have the same shape and the same area as the rectangular shape of the printed circuit board 300, or may have the same shape or a different shape and a small area. That is, in the top view, the side surfaces 1a, 2b, 3c, 4d of the interposer 220 may be located in the same positions as the side surfaces 10a, 20b, 30c, 40d of the printed circuit board 300 located on the same sides of the mounting structure 510, respectively. Also, in the top view, the side surfaces 1a, 2b, 3c, 4d of the interposer 220 may be located inside the side surfaces 10a, 20b, 30c, 40d of the printed circuit board 300 located on the same sides of the mounting structure 510, respectively. That is, the side surfaces 1a, 2b, 3c, 4d of the interposer 220 may be located between the printed circuit board 100 and the printed circuit board 300 in the z-axis direction perpendicular to the main surface of the printed circuit board 100.

As illustrated in FIG. 4C, when the three-dimensional mounting structure 500 is viewed from the upper surface in the z-axis direction, the reinforcing resin portions 410 are formed on four sides of the sides 1, 2, 3, and 4 of the interposer 220 and four sides of the sides 10, 20, 30, and 40 of the printed circuit board 300. The reinforcing resin portion 410 is made of resin 400. The reinforcing resin portion 410 can be formed by applying a resin 400 before curing to an area where the reinforcing resin portion 410 is to be formed and curing the resin 400. Note that, although FIG. 4C illustrates a case where the reinforcing resin portions 410, which are separated into a plurality of portions, are formed at four sides of the sides 10, 20, 30, and 40, some of the plurality of reinforcing resin portions 410 may be integrated and continuous.

Note that the semiconductor element 210 is provided between the reinforcing resin portion 410 formed at the sides 1 and 10 and the reinforcing resin portion 410 formed at the sides 2 and 20 in the y-axis direction. The semiconductor element 210 is provided between the reinforcing resin portion 410 formed at the sides 3 and 30 and the reinforcing resin portion 410 formed at the sides 4 and 40 in the x-axis direction.

For example, a thermosetting resin or an ultraviolet (UV)-curable resin is used for the resin 400. Note that, when the UV-curable resin is used for the resin 400, depending on the size relationship of the external shapes of the semiconductor device 200 and the printed circuit board 300 to be stacked, the UV irradiated when the UV-curable resin is cured may not reach the resin and the UV-curable resin may not be cured. Therefore, the thermosetting resin is preferable as the resin 400 in that the thermosetting resin can be surely cured by heating in a heating means such as an oven. Examples of the constituent materials of the thermosetting resin include an epoxy resin, a filler, a curing agent, and the like. When the thermosetting resin as the resin 400 is cured, the heating temperature must be lower than the melting point of the solder joint 610, the melting point of the solder joint 620, and the heat resistance temperature of the semiconductor device 200, electronic components (not illustrated) and the like other than the mounting structure 510. It is preferable that the cured resin 400 has a bending elastic modulus of several tens of GPa in order to obtain a sufficient reinforcing effect.

In the three-dimensional mounting structure 500, the printed circuit board 100, the interposer 220, and the printed circuit board 300 joined by the solder joint 610 and the solder joint 620 are fixed by the reinforcing resin portions 410. The reinforcing resin portions 410 for fixing them are formed as follows.

FIG. 5A is a sectional view illustrating an enlarged sectional view along the line A-A in FIG. 2, including the side 1 of the interposer 220 and the side 10 of the printed circuit board 300 viewed in the x-axis direction. The x-axis direction is a direction parallel to the longitudinal direction of the reinforcing resin portion 410 provided at the side 1 and the side 10, that is, a direction parallel to the side 1 and the side 10.

As illustrated in FIG. 5A, in the reinforcing resin portion 410, the resin 400 adheres to at least a part of the printed circuit board 100 (for example, a part of the solder resist 151), the side surface 1a of the interposer 220, and a part of the printed circuit board 300 (for example, a part of the solder resist 352). Here, the side surface 1a of the interposer 220 includes a part (end surface) of the solder resist 251, a part (end surface) of the solder resist 252, and a side surface (end surface) of the insulating substrate 230. The resin 400 adhering to the printed circuit board 100, the interposer 220, and the printed circuit board 300 typically contacts the printed circuit board 100, the interposer 220, and the printed circuit board 300. Typically, the resin 400 is formed to contact the surface of the printed circuit board 100 on the side of the interposer 220 and the surface of the printed circuit board 300 on the side of the interposer 220. However, the resin 400 adhering to the printed circuit board 100, the interposer 220, and the printed circuit board 300 may contact the coating or the like applied to at least any of the printed circuit board 100, the interposer 220, and the printed circuit board 300. Thus, the reinforcing resin portion 410 is adhering to the main surface of the printed circuit board 100, the side surface 1a of the interposer 220, and the printed circuit board 300. The resin 400 is formed to partially cover the end surface of the interposer 220 as described later.

In the example of FIG. 5A, the reinforcing resin portion 410 is separated from the solder joint 610 closest to the reinforcing resin portion 410 among the plurality of solder joints 610. Also, the reinforcing resin portion 410 is separated from the solder joint 620 closest to the reinforcing resin portion 410 among the plurality of solder joints 620. Alternatively, as illustrated in FIG. 5B, the resin 400 in the reinforcing resin portion 410 is preferably in contact with the solder joint 610 arranged on the outermost periphery of the plurality of solder joints 610, that is, the solder joints 610 in the row closest to the side 1. That is, the reinforcing resin portion 410 is preferably adhered to the solder joint 610 closest to the reinforcing resin portion 410 among the plurality of solder joints 610. Thus, the resin 400 can more firmly fix the interposer 220 and the printed circuit board 100. Further, the resin 400 is preferably in contact with the solder joint 620 arranged on the outermost periphery of the plurality of solder joints 620, that is, the solder joint 620 in the row closest to the side 10. That is, the reinforcing resin portion 410 is preferably adhered to the solder joint 620 closest to the reinforcing resin portion 410 among the plurality of solder joints 620. Thus, the resin 400 can more firmly fix the interposer 220 and the printed circuit board 300.

The resin 400 in the reinforcing resin portion 410 is formed at a height 421 in the z-axis direction. The height 421 is not less than a height from the surface of the printed circuit board 100 on the side of the main surface 131 to the surface of the printed circuit board 300 on the side of the main surface 332. That is, the height 421 is not less than a height from the surface of the solder resist 151 of the printed circuit board 100 to the surface of the solder resist 352 of the printed circuit board 300.

Here, as illustrated in FIG. 5C, the resin 400 may be formed so as to reach the side surface 10a of the printed circuit board 300. Further, the resin 400 may be formed so as to reach the surface of the printed circuit board 300 on the side of the main surface 331 opposite to the interposer 220, that is, the surface of the solder resist 351. It is important to note that in the reinforcing resin portion 410, the resin 400 is in contact with each of the printed circuit board 100, the interposer 220 and the printed circuit board 300, and the resin 400 is fixed to each of them. Note that, in the case illustrated in FIG. 5C, the height of the reinforcing resin portion 410 in the z-axis direction is not particularly limited, and the reinforcing resin portion 410 may be adhered to the side surface 10a of the printed circuit board 300. When the reinforcing resin portion 410 adheres to the side surface 10a of the printed circuit board 300, the reinforcing resin portion 410 need not adhere to the main surface 331 and/or the main surface 332 of the printed circuit board 300.

As illustrated in FIG. 5A to FIG. 5C, in a side portion 511 of the mounting structure 510 provided with the reinforcing resin portion 410, the resin 400 is formed between the printed circuit board 100 and the printed circuit board 300 so as to cover the side surface of the interposer 220. The reinforcing resin portion 410 has a portion positioned between the printed circuit board 100 and the interposer 220 and a portion positioned between the interposer 220 and the printed circuit board 300 in the z-axis direction perpendicular to the main surface of the printed circuit board 100.

FIG. 5D illustrates a side surface of the reinforcing resin portion 410 provided at the side 1 of the interposer 220 and the side 10 of the printed circuit board 300 viewed in the y-axis direction. As illustrated in FIG. 5D, the reinforcing resin portion 410 is away from at least one of the two ends of the side surface 1a of the interposer 220 in the x-axis direction. That is, the resin 400 in the reinforcing resin portion 410 is formed so that at least one of the two ends of the side surface 1a of the interposer 220 in the x-axis direction is exposed from the reinforcing resin portion 410 without being covered with the resin 400. Further, at least one of the two ends of the side surface 1a of the interposer 220 in the x-axis direction is exposed from the resin 400. Note that the ends of the side surfaces of the interposer 220 correspond to the corners in a quadrilateral consisting of the four sides 1a, 1b, 1c, and 1d, and the ends of the side surfaces refer to the ends and the portions near the ends. The side surface 1a and the side surface 3c are connected to each other at one end of the side surface 1a and one end of the side surface 3c, and the side surface 2a and the side surface 4d are connected to each other at one end of the side surface 2a and one end of the side surface 4d. The side surface 1a and the side surface 4d are connected to each other at the other end of the side surface 1a and the other end of the side surface 4d, and the side surface 3a and the side surface 4d are connected to each other at the other end of the side surface 3a and the other end of the side surface 4d. Here, the reinforcing resin portion 410 has a length 411 in the x-axis direction. Specifically, in the side 1 and the side 10 at which the reinforcing resin portion 410 is formed, the length 411 of the reinforcing resin portion 410 is shorter than the length of the side 1 of the interposer 220. That is, the reinforcing resin portion 410 is shorter than the interposer 220 in the x-axis direction along the side portion 511 of the mounting structure 510, which will be described later. Here, the resin 400 in the reinforcing resin portion 410 is preferably formed so that the two ends of the side 1a of the interposer 220 in the x-axis direction are exposed from the reinforcing resin portion 410 without being covered with the resin 400. This is because having the side surfaces 1a exposed not at one end but at the two ends provides a better balance of the reinforcing effect of the reinforcing resin portion 410 with respect to the three-dimensional mounting structure 500.

On the other hand, when the reinforcing resin portion 410 is viewed in the y-axis direction, the solder joints 610 and 620 are covered with the resin 400 in the reinforcing resin portion 410 and are not exposed. Note that, as in a second embodiment described later, the solder joints 610 and 620 may be exposed from the resin 400 without being covered with the resin 400 on both sides of the reinforcing resin portion 410 in the x-axis direction.

Note that, although the reinforcing resin portion 410 provided at the side 1 and the side 10 of the interposer 220 and the printed circuit board 300 has been described above, other reinforcing resin portions 410 have the same structure as the above. That is, the reinforcing resin portion 410 provided at the side 2 and the side 20 of the interposer 220 and the printed circuit board 300 have the same structure as the reinforcing resin portion 410 provided at the side 1 and the side 10 above. The reinforcing resin portions 410 provided at the side 3 and the side 30 and at the side 4 and the side 40 of the interposer 220 and the printed circuit board 300 also have the same structure as the reinforcing resin portion 410 provided at the side 1 and the side 10 except that the x-axis direction and the y-axis direction are exchanged.

Thus, in the three-dimensional mounting structure 500 according to the present embodiment, the reinforcing resin portion 410 is formed at each of the side portions 511, 512, 513 and 514 of the mounting structure 510. Here, the side portion 511 of the mounting structure 510 includes the side 1 of the interposer 220 and the side 10 of the printed circuit board 300. The side portion 512 includes the side 2 of the interposer 220 and the side 20 of the printed circuit board 300. The side portion 513 includes the side 3 of the interposer 220 and the side 30 of the printed circuit board 300. The side portion 514 includes the side 4 of the interposer 220 and the side 40 of the printed circuit board 300. In respective side portions 511, 512, 513, and 514, when the side surfaces 1a, 1b, 1c, and 1d of one or the two of both ends of the interposer 220 are exposed from the resin 400, some or all of the four corners of the interposer 220 are exposed from the resin 400. Note that the reinforcing resin portion 410 may be provided at at least two side portions of the side portions 511, 512, 513, and 514 that are opposite each other.

The reinforcing resin portion 410 may be provided away from at least one of the two ends of the side surface 1a of the interposer 220 in the x-axis direction and away from at least one of the two ends of the side surface 2b of the interposer 220 in the x-axis direction. In this case, one end of the side surface 1a from which the reinforcing resin portion 410 is away may be closer to the side surface 3d than to the side surface 4d, and one end of the side surface 2b from which the reinforcing resin portion 410 is away may be closer to the side surface 4d than to the side surface 3c. In this way, since exposed portions without the reinforcing resin portion 410 are arranged at opposite corners in the rectangular planar shape of the interposer 220, the reinforcing effect by the resin 400 can be obtained more equally.

The reinforcing resin portion 410 may be arranged away from one end and the other end of the two ends of the side surface 1a of the interposer 220 in the x-axis direction and away from one end and the other end of the two ends of the side surface 2b of the interposer 220 in the x-axis direction.

With the reinforcing resin portion 410 formed in this manner, the reinforcing effect by the resin 400 can be sufficiently obtained. In the three-dimensional mounting structure 500, stress is concentrated in the solder joints 610 and 620 in the vicinity of the portions where the resin 400 is not formed. To address this, the structure in which some or all of the four corners of the interposer 220 are exposed from the resin 400 can reduce the stress concentration. This is because the stress is dispersed in the solder joints 610 and 620 near the four corners where the resin 400 is not formed. Further, since the four corners of the interposer 220 are exposed from the resin 400 and are not reinforced with the resin 400, when the deformation occurs in the interposer 220 or the printed circuit board 300, the deformation can be released from the four corners. Thus, the joining by the solder joints 610 and 620 can be reinforced while avoiding the occurrence of a defect due to the deformation in the interposer 220 and the printed circuit board 300.

As described above, according to the present embodiment, the reliability of the solder joints in the three-dimensional mounting structure 500 can be improved.

Note that, as for the thickness of the interposer 220 and the thickness of the printed circuit board 300, as illustrated in FIG. 5E, the thickness 301 of the printed circuit board 300 is preferably smaller than the thickness 221 of the interposer 220. When the thickness 301 is smaller than the thickness 221, the rigidity of the printed circuit board 300 is relatively lower than the rigidity of the interposer 220. Thus, when the printed circuit board 300 is deformed by heat, the influence of the interposer 220 having higher rigidity than the printed circuit board 300 is reduced. As a result, the stress applied to the solder joints 610 and 620 where the resin 400 is not formed is reduced. Thus, the thickness 301 is thinner than the thickness 221, thereby further improving the reliability of the solder joints in the three-dimensional mounting structure 500.

Further, the planar shapes of the interposer 220 and the printed circuit board 300 in the top view viewed in the z-axis direction are not limited to a rectangle, but may be a shape such as a polygon which may include a side at which the reinforcing resin portion 410 is formed as described above. Further, the sides of the interposer 220 and the printed circuit board 300 at which the reinforcing resin portion 410 is formed may be not only linear but also curved.

### Second Embodiment

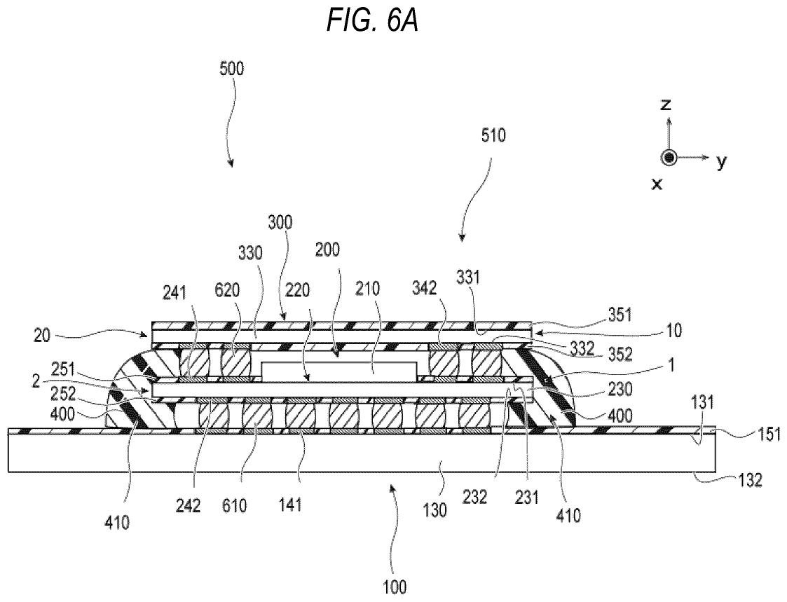

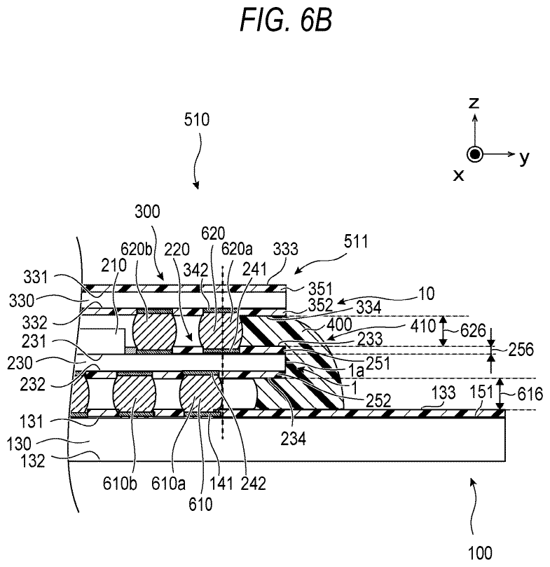

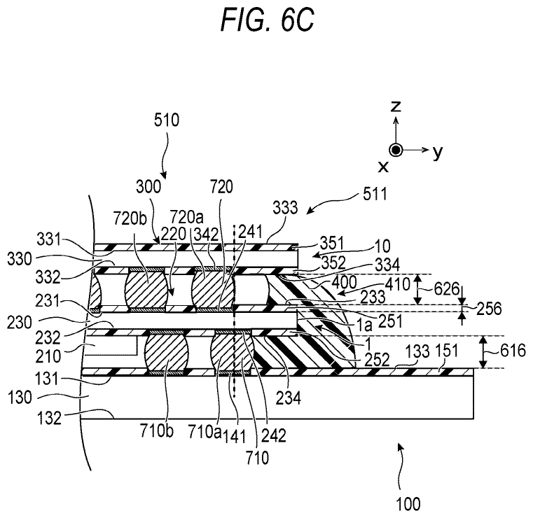

A three-dimensional mounting structure 500 according to a second embodiment of the present disclosure will be described with reference to FIG. 6A to FIG. 6C. Note that the same components as those in the first embodiment will be labeled with the same reference numerals and the detailed description thereof will be omitted or simplified.

The basic structure of the three-dimensional mounting structure 500 according to the present embodiment is the same as that of the three-dimensional mounting structure 500 according to the first embodiment. In the three-dimensional mounting structure 500 according to the present embodiment, the relationship between the resin 400 of the reinforcing resin portion 410 and the solder joints 610 and 620 is different from that in the first embodiment.

FIG. 6A is a cross-sectional view illustrating the three-dimensional mounting structure 500 according to the present embodiment, which corresponds to the cross-sectional view of FIG. 3. FIG. 6B is an enlarged view illustrating an enlarged cross-sectional view of the three-dimensional mounting structure 500 according to the present embodiment. FIG. 6C is an enlarged view illustrating another example of the cross-sectional view of the three-dimensional mounting structure 500 according to the present embodiment. FIG. 6B and FIG. 6C are enlarged views corresponding to FIG. 5A, respectively, and illustrate a cross-sectional view including the side 1 of the interposer 220 and the side 10 of the printed circuit board 300 viewed in the x-axis direction.

As illustrated in FIG. 6A, in the three-dimensional mounting structure 500 according to the present embodiment, the plurality of lands 141 and the plurality of lands 242 are joined by the solder joints 610, as in the first embodiment. Further, the plurality of lands 241 and the plurality of lands 342 are joined by the solder joints 620. As illustrated in FIG. 6C, in another example of the three-dimensional mounting structure 500 according to the present embodiment, the plurality of lands 141 and the plurality of lands 242 are joined by solder joints 710. Further, the plurality of lands 241 and the plurality of lands 342 are joined by solder joints 720.

As illustrated in FIG. 6B, the solder joints 610 includes solder joints 610a located at the outermost periphery and solder joints 610b located inside the solder joints 610a. The solder joint 620 includes solder joints 620a located at the outermost periphery and solder joints 620b located inside the solder joints 620a. As illustrated in FIG. 6C, the solder joints 710 includes solder joints 710a located at the outermost periphery and solder joints 710b located inside the solder joint 710a. The solder joints 720 includes solder joints 720a located at the outermost periphery and solder joints 720b located inside the solder joint 720a.

The solder joints 610 and 710 are formed at a height 616 in the z-axis direction. The height 616 is a height from the main surface 133 of the solder resist 151 to the main surface 234 of the solder resist 252. The solder joints 620 and 720 are formed at a height 626 in the z-axis direction. The height 626 is a height from the main surface 233 of the solder resist 251 to the main surface 334 of the solder resist 352. Note that the solder resist 251 has a thickness 256. Note also that the solder resist 351 formed on the main surface 331 of the insulating substrate 330 in the printed circuit board 300 has a main surface 333.

The semiconductor element 210 may be mounted on the main surface 231 of the insulating substrate 230 as illustrated in FIG. 6A and FIG. 6B, or may be mounted on the main surface 232 of the insulating substrate 230 as illustrated in FIG. 6C.

As illustrated in FIG. 6B, when the semiconductor element 210 is mounted on the main surface 231 of the insulating substrate 230, the outermost peripheral position of the solder joint 610a in the y-axis direction is inside the center position of the solder joint 620a in the y-axis direction. Also, as illustrated in FIG. 6C, when the semiconductor element 210 is mounted on the main surface 232 of the insulating substrate 230, the outermost peripheral position of the solder joint 720a in the y-axis direction is inside the center position of the solder joint 710a in the y-axis direction.

In the top view of the three-dimensional mounting structure 500 viewed from the top surface in the z-axis direction, the reinforcing resin portion 410 is formed at four sides of the sides 1, 2, 3, and 4 of the interposer 220 and four sides 10, 20, 30, and 40 of the printed circuit board 300 as in the first embodiment.

In the three-dimensional mounting structure 500 according to the present embodiment also, as illustrated in FIG. 6A, the printed circuit board 100, the interposer 220, and the printed circuit board 300 joined by the solder joints 610 and the solder joints 620 are fixed by the reinforcing resin portion 410. Also, as illustrated in FIG. 6C, the printed circuit board 100, the interposer 220, and the printed circuit board 300 joined by the solder joints 710 and the solder joints 720 are fixed by the reinforcing resin portion 410.

As illustrated in FIG. 6B and FIG. 6C, in the reinforcing resin portion 410, the resin 400 adheres to at least a part of the printed circuit board 100 (for example, a part of the solder resist 151), the side surface 1a of the interposer 220, and a part of the printed circuit board 300 (for example, a part of the solder resist 352). The resin 400 adhering to the printed circuit board 100, the interposer 220, and the printed circuit board 300 typically contacts the printed circuit board 100, the interposer 220, and the printed circuit board 300. Typically, the resin 400 is formed to contact the surface of the printed circuit board 100 on the side of the interposer 220 and the surface of the printed circuit board 300 on the side of the interposer 220. However, the resin 400 adhering to the printed circuit board 100, the interposer 220 and the printed circuit board 300 may contact the coating or the like applied to at least any of the printed circuit board 100, the interposer 220 and the printed circuit board 300. Thus, the reinforcing resin portion 410 is adhering to the main surface of the printed circuit board 100, the side surface 1a of the interposer 220 and the printed circuit board 300. The resin 400 is formed to partially cover the end surface of the interposer 220.

In the present embodiment, as illustrated in FIG. 6B, the resin 400 in the reinforcing resin portion 410 is in contact with the solder joint 620a located on the outermost periphery, but not with the solder joint 610a located on the outermost periphery. That is, the reinforcing resin portion 410 adheres to the solder joint 620a closest to the reinforcing resin portion 410 among the plurality of solder joints 620, and is not adhered to the solder joint 610a closest to the reinforcing resin portion 410 among the plurality of solder joints 610.

Note that, in FIG. 6B, the distance between the solder joint 610a closest to the reinforcing resin portion 410 among the plurality of solder joints 610 and the side surface 1a is longer than the distance between the solder joint 620a closest to the reinforcing resin portion 410 among the plurality of solder joints 620 and the side surface 1a.

Note that the contact relationship between the resin 400 in the reinforcing resin portion 410 and the solder joints 610a and 620a may be opposite to the relationship illustrated in FIG. 6B. That is, one solder joint group of the plurality of solder joints 610 and the plurality of solder joints 620 may have a relationship to adhere to the resin 400 and the other solder joint group may have a relationship not to adhere to the resin 400. More specifically, as illustrated in FIG. 6C, the resin 400 in the reinforcing resin portion 410 may contact the solder joint 710a located on the outermost periphery, and may not contact the solder joint 720a located on the outermost periphery. That is, the reinforcing resin portion 410 may adhere to the solder joint 710a closest to the reinforcing resin portion 410 among the plurality of solder joints 710, and may not adhere to the solder joint 720a closest to the reinforcing resin portion 410 among the plurality of solder joints 720.

Note that, in the case illustrated in FIG. 6C, the distance between the solder joint 720a closest to the reinforcing resin portion 410 among the plurality of solder joints 720 and the side surface 1a is longer than the distance between the solder joint 710a closest to the reinforcing resin portion 410 among the plurality of solder joints 710 and the side surface 1a.

Note also that the resin 400 in the reinforcing resin portion 410 formed on the sides 2, 3, and 4 other than the side 1 of the interposer 220 and the sides 20, 30, and 40 other than the side 10 of the printed circuit board 300 may also be formed so as to have the same relationship as that illustrated in FIG. 6B or FIG. 6C.

By forming the reinforcing resin portion 410 in this manner, the reinforcing effect of the resin 400 can be sufficiently obtained. When the resin 400 is not formed at all four sides of the interposer 220 and the printed circuit board 300, the reliability of the solder joints can be improved as follows. That is, particularly in the three-dimensional mounting structure 500 in which the resin 400 is not formed as illustrated in FIG. 6B, the number of solder joints is smaller in the solder joint 620 on which the semiconductor element 210 is mounted than in the solder joint 610, so that stress is concentrated in the solder joints 620a. In contrast, when the reinforcing resin is formed at at least two opposite sides of the interposer 220 and the printed circuit board 300, stress in the solder joints 620a is reduced. At this time, since the solder joint 610a at the side where the resin 400 is formed is not in contact with the resin 400, stress is also dispersed in the solder joint 610a, which was originally not stressed due to the resin 400 being in contact. Therefore, as the stress applied to the solder joint 610a at the side where the resin 400 is formed is increased, the stress applied to the solder joint 620a at the side where the resin 400 is not formed is decreased. Thus, the reliability of the solder joints as a whole of the three-dimensional mounting structure 500 can be improved. Further, in the three-dimensional mounting structure 500 in which the resin 400 is not particularly formed as illustrated in FIG. 6C, the number of solder joints is smaller in the solder joint 710 on which the semiconductor element 210 is mounted than in the solder joint 720, so that stress is concentrated in the solder joint 710a. In contrast, when the reinforcing resin 400 is formed at at least two opposite sides of the interposer 220 and the printed circuit board 300, stress in the solder joint 710a is reduced. At this time, since the solder joint 720a at the side where the resin 400 is formed is not in contact with the resin 400, stress is also dispersed in the solder joint 720a, which was originally not stressed due to the resin 400 being in contact. Therefore, as the stress applied to the solder joint 720a at the side where the resin 400 is formed is increased, the stress applied to the solder joint 710a at the side where the resin 400 is not formed is decreased. Thus, the reliability of the solder joints as a whole of the three-dimensional mounting structure 500 can be improved.

### Third Embodiment

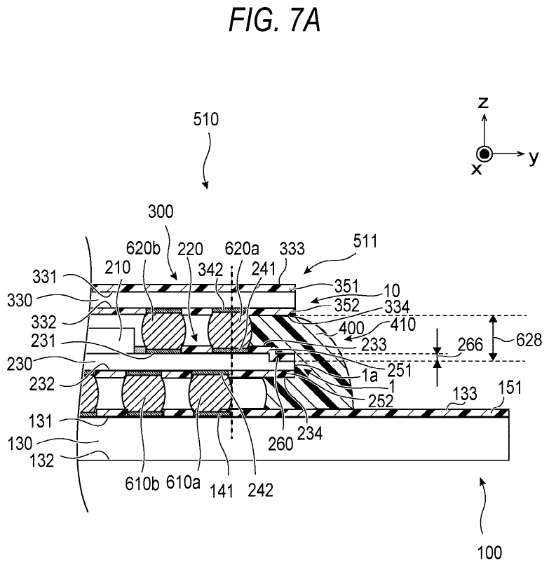

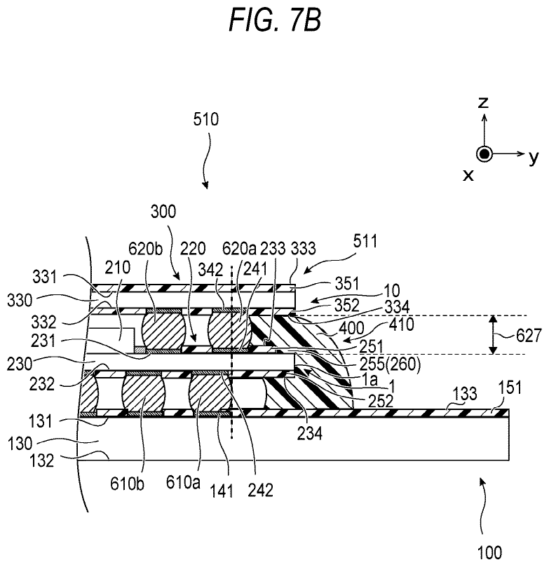

A three-dimensional mounting structure according to a third embodiment of the present disclosure will be described with reference to FIG. 7A and FIG. 7B. Note that the same components as those in the first and second embodiments will be labeled with the same reference numerals and the detailed description thereof will be omitted or simplified.

The basic structure of the three-dimensional mounting structure 500 according to the present embodiment is the same as that of the three-dimensional mounting structure 500 according to the second embodiment. The three-dimensional mounting structure 500 according to the present embodiment differs from that of the second embodiment in that a step, which is a recess, is formed in a portion outside the solder joint 620a in the interposer 220.

FIG. 7A is a cross-sectional view illustrating the three-dimensional mounting structure 500 according to the present embodiment, which corresponds to the cross-sectional view of FIG. 6B. As illustrated in FIG. 7A, in the present embodiment, a portion of the main surface 231 of the insulating substrate 230 located outside the solder joint 620a located on the outermost periphery is eliminated, and a step 260, which is a recess, is formed. The reinforcing resin portion 410 is formed over the step 260. The range of the step 260 formed on the outside of the plurality of solder joints 620 is extended in a rectangular annular shape in the x-axis direction and the y-axis direction so as to surround the outermost periphery of the solder joint 620a. The step 260 has a height 266. The step 260 may reach the end of the interposer 220 or may be formed between the solder joint 620a and the end of the interposer 220. At this time, the height between the interposer 220 and the printed circuit board 300 is a height 628 in the z-axis direction at the portion where the step 260 exists. The height 628 is a height from the main surface 231 of the step 260 of the insulating substrate 230 to the main surface 234 of the solder resist 352.

The resin 400 of the reinforcing resin portion 410 enters a portion having the step 260 at the side where the reinforcing resin portion 410 is formed. Due to the presence of the step 260, the height 628 in which the resin 400 permeates is increased by the height 266 of the step 260 with respect to the height 626 illustrated in FIG. 6B in which the step 260 does not exist. In this way, when there is the step 260, the height at which the resin 400 permeates becomes higher, so that the resin 400 permeates more easily.

In addition, the step 260 need not necessarily be formed by eliminating a part of the insulating substrate 230. FIG. 7B is a cross-sectional view illustrating another example of the step 260. For example, as illustrated in FIG. 7B, the step 260 may be formed as an opening 255 from which a part of the solder resist 251 provided on the main surface 231 of the insulating substrate 230 located outside the solder joint 620a located on the outermost periphery thereof is removed. In this case, the height between the interposer 220 and the printed circuit board 300 becomes the height 627 in the z-axis direction at a portion having the opening 255. The height 627 is the height from the main surface 231 of the insulating substrate 230 to the main surface 234 of the solder resist 352.

As in the present embodiment, the step 260 may be formed on the outside of the solder joint 620a located at the outermost periphery, and the resin 400 of the reinforcing resin portion 410 may be formed to enter the step 260. Thus, the resin 400 of the reinforcing resin portion 410 can be more easily inserted between the interposer 220 and the printed circuit board 300, and the resin 400 can be brought into contact with the solder joint 620a more firmly.

Note that the step 260 may be provided in the three-dimensional mounting structure 500 according to the first embodiment in the same manner as in the present embodiment.

### Fourth Embodiment

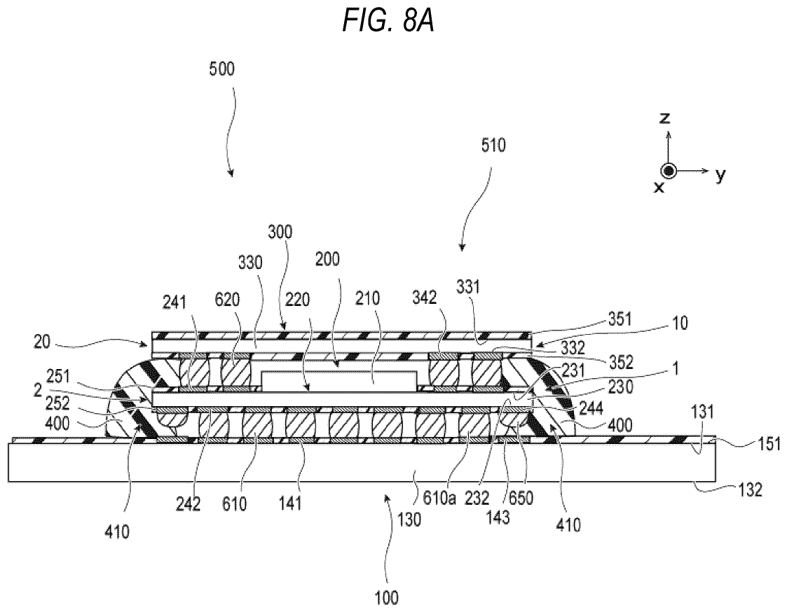

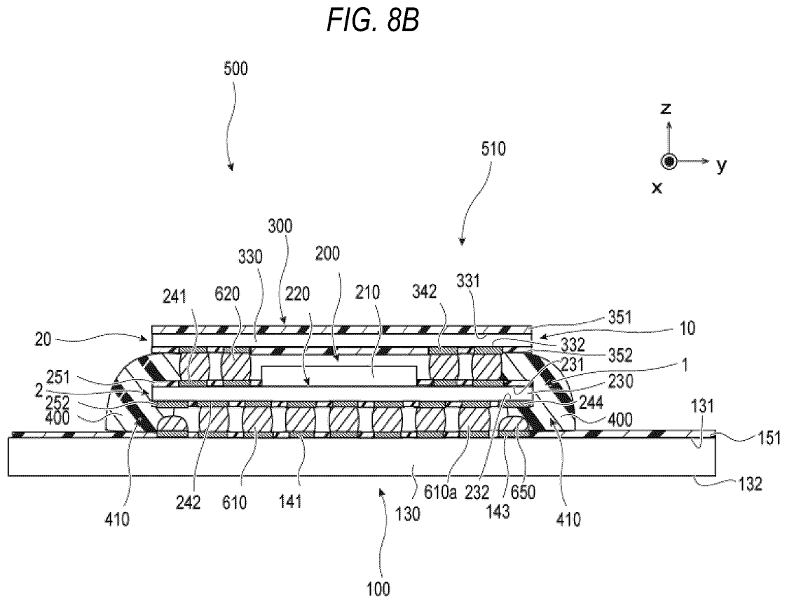

A three-dimensional mounting structure 500 according to a fourth embodiment of the present disclosure will be described with reference to FIG. 8A and FIG. 8B. Note that the same components as those in the first to third embodiments will be labeled with the same reference numerals and the detailed description thereof will be omitted or simplified.

The basic structure of the three-dimensional mounting structure 500 according to the present embodiment is the same as that of the three-dimensional mounting structure 500 according to the second embodiment. The three-dimensional mounting structure 500 according to the present embodiment differs from that of the second embodiment in that dummy bumps 650, which are solder portions, is provided outside the solder joint 610a located at the outermost periphery.

FIG. 8A is a sectional view illustrating the three-dimensional mounting structure 500 according to the present embodiment, and is a sectional view corresponding to the sectional view of FIG. 6A. As illustrated in FIG. 8A, the printed circuit board 100 has lands 143 arranged on the outer periphery of the lands 141 on the main surface 131. The interposer 220 also has lands 244 arranged on the outer periphery of the lands 242 on the main surface 232 of the insulating substrate 230. Dummy bumps 650 which is solder portions are mounted on the lands 244. The dummy bump 650 has a height lower than the height 616 (see FIG. 6B) and is not joined to the land 143. Therefore, a gap exists between the dummy bump 650 and the printed circuit board 100.

FIG. 8B is a cross-sectional view illustrating another example of the dummy bumps 650. As illustrated in FIG. 8B, the dummy bumps 650 may be mounted on the lands 143 on the side of the printed circuit board 100 rather than on the land 244 on the side of the interposer 220. In this case, a gap exists between the dummy bump 650 and the interposer 220.

In this way, the dummy bumps 650 provided between the printed circuit board 100 and the interposer 220 are provided so as not to be joined to either the printed circuit board 100 or the interposer 220. The reinforcing resin portion 410 adheres to the dummy bumps 650.

Since the dummy bump 650 is provided as described above, the penetration of the resin 400 of the reinforcing resin portion 410 in the mounting structure 510 is prevented. Thus, in the three-dimensional mounting structure 500 according to the present embodiment, the resin 400 is formed so as not to contact the solder joint 610a located at the outermost periphery, as in the second embodiment.

Note that, as illustrated in FIG. 6C, when the semiconductor element 210 is mounted on the main surface 232 of the insulating substrate 230, the dummy bumps 650 may be provided outside the solder joint 720a rather than outside the solder joint 710a.

Note also that the dummy bumps 650 may also be provided in the three-dimensional mounting structure 500 according to the first or third embodiments in the same manner as in the present embodiment.

### Fifth Embodiment

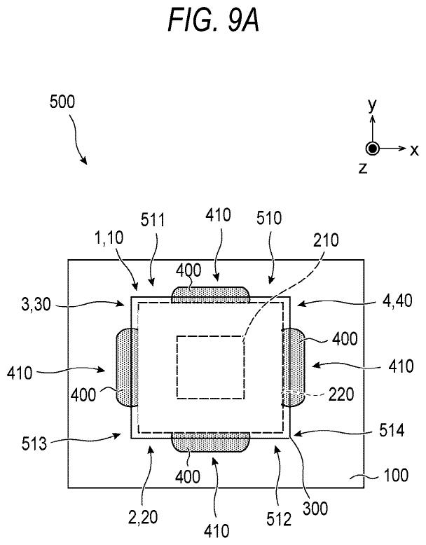

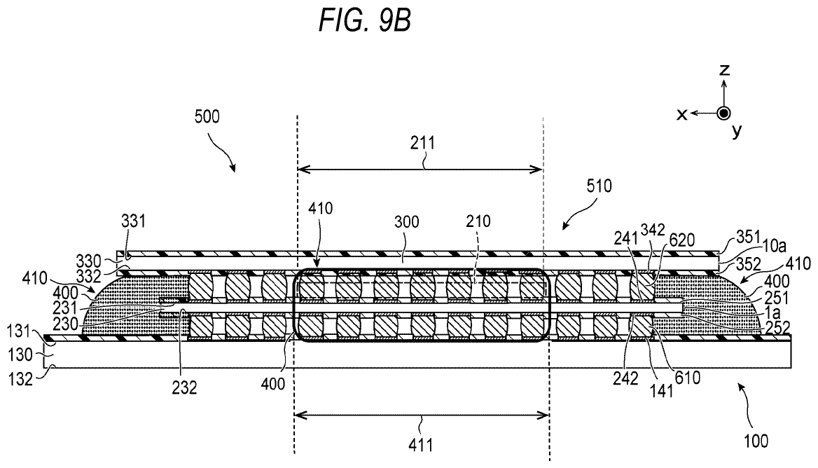

A three-dimensional mounting structure according to a fifth embodiment of the present disclosure will be described with reference to FIG. 9A and FIG. 9B. FIG. 9A is a top view illustrating the three-dimensional mounting structure according to the present embodiment. FIG. 9B is a side view of the three-dimensional mounting structure 500 according to the present embodiment viewed from the y-axis direction. Note that the same components as those in the first to fourth embodiments will be labeled with the same reference numerals and the detailed description thereof will be omitted or simplified.

As illustrated in FIG. 9A and FIG. 9B, in the present embodiment, compared with the first embodiment, the length 411 of the reinforcing resin portion 410 is shortened in the x-axis direction, which is a direction along a side portion 511 of the mounting structure 510 provided with the reinforcing resin portion 410. As illustrated in FIG. 9B, in the present embodiment, the reinforcing resin portion 410 is provided at a position overlapping the projected semiconductor element 210 when the semiconductor element 210 is projected in the y-axis direction. That is, in the side view of the side portion 511 of the mounting structure 510, the reinforcing resin portion 410 is provided so as to include a region where the semiconductor element 210 and the solder joints 620 overlap.

Note that in the side view of the side portion 511 of the mounting structure 510, the outermost solder joint 610 among the plurality of solder joints 610 is arranged at the same position as the outermost solder joint 620 among the plurality of solder joints 620, but the arrangement is not limited thereto. In the side view of the side portion 511 of the mounting structure 510, the outermost solder joint 610 among the plurality of solder joints 610 may be arranged inside the outermost solder joint 620 among the plurality of solder joints 620.

In the x-axis direction, which is a direction along the side portion 511 of the mounting structure 510, the length 411 of the reinforcing resin portion 410 is longer than the length of the semiconductor element 210, that is, the length 211 of the side of the projected semiconductor element 210. Thus, in the x-axis direction, the length 411 of the reinforcing resin portion 410 may be shorter than that of the first embodiment if the length 411 is longer than the length 211 of the side of the semiconductor element 210. As the length 411 of the reinforcing resin portion 410 is short in such a way, when the reinforcing resin portion 410 is viewed from the y-axis direction, the solder joints 610 and 620 may be exposed from the resin 400 without being covered with the resin 400 on both sides of the reinforcing resin portion 410 in the x-axis direction.

Thus, in the present embodiment, the solder joints 610 arranged on the outermost periphery among the plurality of solder joints 610 are exposed from the resin 400 on both ends of the side portions 511 of the mounting structure 510 provided with the reinforcing resin portion 410. That is, the reinforcing resin portion 410 is separated from the solder joints 610 closest to one end and the other end in the x-axis direction of the side surface 1a of the interposer 220 among the plurality of solder joints 610. Note that the plurality of solder joints 610 arranged on the outermost periphery among the plurality of solder joints 610 may be exposed from the resin 400 on one end side of the side portion 511 of the mounting structure 510. In the present example, among the solder joints 610 arranged on the outermost periphery, three solder joints 610 up to the third in order of a short distance from one end in the x-axis direction of the side surface 1a of the interposer 220 are exposed from the resin 400. The same is true on the side of the other end in the x-axis direction of the side surface 1a of the interposer 220. On both ends of the side portions 511 of the mounting structure 510, the solder joints 620 arranged on the outermost periphery of the plurality of solder joints 620 are exposed from the resin 400. That is, the reinforcing resin portion 410 is separated from the solder joints 620 closest to one end and the other end in the x-axis direction of the side surface 1a of the interposer 220 among the plurality of solder joints 620. Note that the plurality of solder joints 620 arranged on the outermost periphery of the plurality of solder joints 620 may be exposed from the resin 400 at one end of the side portion 511 of the mounting structure 510. In the present example, among the solder joints 610 arranged on the outermost periphery, three solder joints 620 up to the third in order of a short distance from one end in the x-axis direction of the side surface 1a of the interposer 220 are exposed from the resin 400. The same is true on the side of the other end in the x-axis direction of the side surface 1a of the interposer 220.

Note that, although the reinforcing resin portion 410 provided at the side 1 of the interposer 220 and the side 10 of the printed circuit board 300 have been described above, other reinforcing resin portions 410 may have the same structure as the above as illustrated in FIG. 9A. That is, the reinforcing resin portion 410 provided on the side 2 and the side 20 of the interposer 220 and the printed circuit board 300 may have the same structure as the reinforcing resin portion 410 provided on the side 1 and the side 10. Further, the reinforcing resin portion 410 provided on the side 3 and the side 30 and the side 4 and the side 40 of the interposer 220 and the printed circuit board 300 may have the same structure as the reinforcing resin portion 410 provided on the sides 1 and 10 except that the x-axis direction and the y-axis direction are exchanged.

In the present embodiment also, the stress dispersion effect described in the first embodiment, that is, the stress dispersion effect in the solder joints 610 and 620 in the vicinity of the four corners where the reinforcing resin portion 410 is not formed, can be sufficiently obtained. Further, since the reinforcing resin portion 410 is provided so as to include a region where the semiconductor element 210 and the solder joint 620 overlap each other, the solder joint where the stress is concentrated most can be reinforced. Thus, the reliability of the solder joints in the three-dimensional mounting structure can be improved by applying the resin at least longer than the semiconductor element and exposing the end of the side surface of the interposer from the resin. Therefore, according to the present embodiment, the reliability of the solder joints in the three-dimensional mounting structure 500 can be sufficiently maintained. Further, by shortening the length of the resin in the range described in the present embodiment and reducing the amount of resin applied compared with the first embodiment, the cost of the resin can be reduced.

Note that, in the three-dimensional mounting structure 500 according to the second, third or fourth embodiment, the length 411 of the reinforcing resin portion 410 may be shortened as in the present embodiment.

### Sixth Embodiment

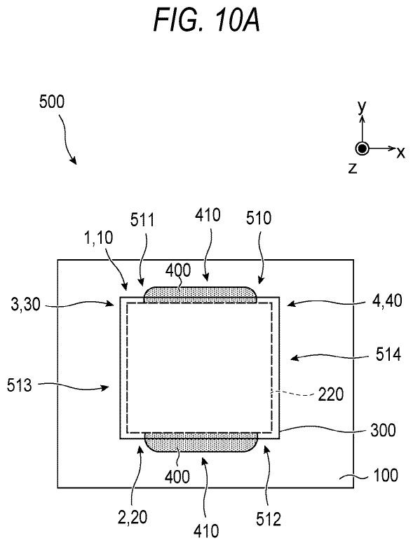

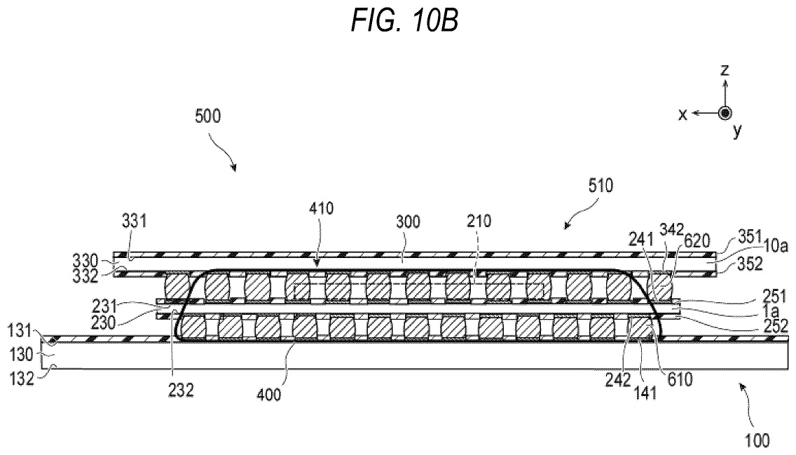

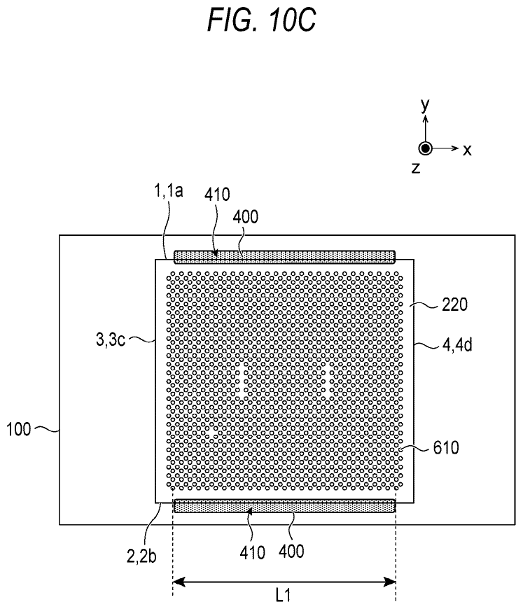

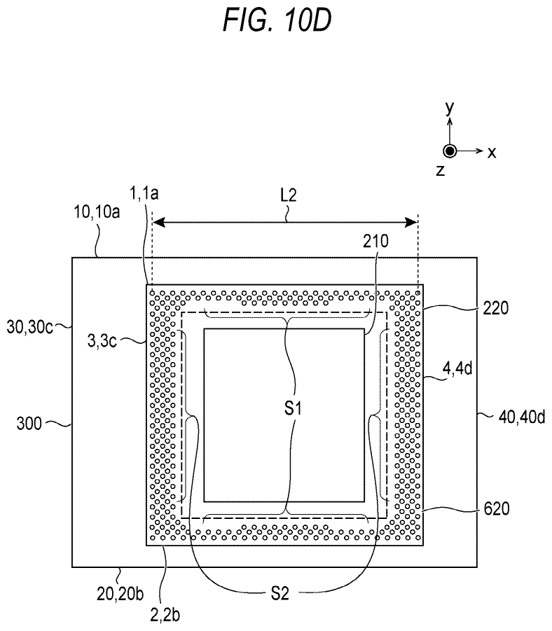

A three-dimensional mounting structure 500 according to a sixth embodiment of the present disclosure will be described with reference to FIG. 10A to FIG. 10D. FIG. 10A is a top view illustrating the three-dimensional mounting structure 500 according to the present embodiment. FIG. 10B is a side view of the three-dimensional mounting structure 500 according to the present embodiment viewed from the y-axis direction. FIG. 10C is a plan view illustrating the solder joints 610. FIG. 10D is a plan view illustrating the solder joints 620. Note that the same components as those in the first to fifth embodiments will be labeled with the same reference numerals and the detailed description thereof will be omitted or simplified.

In the first to fifth embodiments, the reinforcing resin portion 410 is formed at each of four sides of the mounting structure 510 corresponding to the four sides of the interposer 220 and the four sides of the printed circuit board 300. On the other hand, in the present embodiment, side portions of the mounting structure 510 at which the reinforcing resin portion 410 is formed are made two side portions out of the four side portions. Note that, in the present embodiment, the reinforcing resin portion 410 formed at the two side portions and its surrounding structure can have the same structure as any of the first to fifth embodiments.

As illustrated in FIG. 10A, in the present embodiment, the reinforcing resin portion 410 is formed at each of the two side portions 511 and 512 of the mounting structure 510 opposing each other. The side portion 511 of the mounting structure 510 includes the side 1 of the interposer 220 and the side 10 of the printed circuit board 300. The side portion 512 of the mounting structure 510 includes the side 2 of the interposer 220 and the side 20 of the printed circuit board 300.

On the other hand, no reinforcing resin portions 410 is formed at the two side portions 513 and 514 of the mounting structure 510 opposing each other. The side portions 513 of the mounting structure 510 includes the side 3 of the interposer 220 and the side 30 of the printed circuit board 300. The side portions 514 of the mounting structure 510 includes the side 4 of the interposer 220 and the side 40 of the printed circuit board 300. That is, no resin portion made of the same material as the reinforcing resin portion 410 is adhered to the side surfaces 3c and 4c of the interposer 220.

In the present embodiment, for example, it is assumed that the sides 10 and 20 of the printed circuit board 300 are about 1.1 times longer than the sides 1 and 2 of the interposer 220, and the sides 30 and 40 of the printed circuit board 300 are about the same length as the sides 3 and 4 of the interposer 220. That is, the sides 3 and 4 of the interposer 220 are hidden under the printed circuit board 300 where the sides 30 and 40 are located outside the interposer 220. In this case, as illustrated in FIG. 10A, the reinforcing resin portion 410 is formed at each of the two side portions 511 and 512 of the mounting structure 510 opposing each other. The side portion 511 includes the side 1 of the interposer 220 and the side 10 of the printed circuit board 300. The side portion 512 includes the side 2 of the interposer 220 and the side 20 of the printed circuit board 300. Further, as illustrated in FIG. 10B, when the three-dimensional mounting structure 500 is viewed from the y-axis direction, the solder joints 610 are hidden by the reinforcing resin portion 410 at the side portion 511 and are not visible. On the other hand, the outermost solder joints 620 among the plurality of solder joints 620 are arranged outside the outermost solder joints 610 among the plurality of solder joints 610, and one solder joint 610 is exposed from each of both ends of the reinforcing resin portion 410. Note that the side portion 512 of the mounting structure 510 has the same structure as the above. Thus, the stress concentrated in the solder joints 610 near the side portion 513 and the side portion 514 can be dispersed in the solder joints 620 exposed from both ends of the resin of the side portion 511 and the side portion 512. Therefore, according to the present embodiment, the reliability of the solder joints of the three-dimensional mounting structure 500 can be improved as compared with the case where the reinforcing resin portion 410 is formed at the two sides of the mounting structure 510 so as to cover the sides 1 and 2 of the interposer 220.

Furthermore, depending on the production tact, it may be necessary to shorten the time required for coating the resin 400. In this case, by forming the reinforcing resin portion 410 at the two side portions 511 and 512 of the mounting structure 510 as in the present embodiment, the time required for coating the resin 400 can be shortened and the reliability of the solder joints can be sufficiently secured.

Here, FIG. 10C and FIG. 10D illustrates the arrangement of the solder joints 610 and 620 as viewed from the z-axis direction. The distance between the solder joint 610 closest to one end of the side surface 1a in the x-axis direction among the plurality of solder joints 610 and the solder joint 610 closest to the other end of the side surface 1a in the x-axis direction among the plurality of solder joints 610 is set to L1. The distance between the solder joint 620 closest to one end of the side surface 1a in the x-axis direction among the plurality of solder joints 620 and the solder joint 620 closest to the other end of the side surface 1a in the x-axis direction among the plurality of solder joints 620 is set to L2. Then, the distance L2 may be larger than the distance L1.

It is also possible that the solder joints 610 or the solder joints 620 are not arranged on the side of the four side portions 511, 512, 513, and 514 of the mounting structure 510 in an equal number of lines, and that the number of lines is less on the side of the two side portions opposing each other. In this case, it is preferable that the reinforcing resin portion 410 is formed at the two side portions having less number of lines of the solder joints 610 or the solder joints 620. This is because the portion having less number of lines of the solder joints is more likely to break when the stress is concentrated than the portion having more number of lines, and the reinforcing effect is effectively exerted by forming the reinforcing resin portion 410 preferentially on the portion with less number of lines to reduce the stress. For example, the plurality of solder joints 610 or the plurality of solder joints 620 are provided with less number of lines at the side portions 511 and 512 provided with the reinforcing resin portion 410 than at the side portions 513 and 514 provided without the reinforcing resin portion 410. Here, the sum of the number of solder joints 620 positioned between the semiconductor element 210 and the side surface 1a of the interposer 220 in the y-axis direction and the number of solder joints 620 positioned between the semiconductor element 210 and the side surface 2b of the interposer 220 in the y-axis direction is taken as S1. Further, the sum of the number of solder joints 620 positioned between the semiconductor element 210 and the side surface 3c of the interposer 220 in the x-axis direction and the number of solder joints 620 positioned between the semiconductor element 210 and the side surface 4d of the interposer 220 in the x-axis direction is taken as S2. Then, in the example where there is a difference in the number of columns, the sum S1 is less than the sum S2.

### EXAMPLES

### Example 1

Example 1 corresponding to the first embodiment will be described below.

The sizes of the respective portions of the three-dimensional mounting structure 500 were as follows. The outer shape of the interposer 220 was 16.40 mm in length for the side 1 and the side 2, and 15.20 mm in length for the side 3 and the side 4, respectively. The thickness of the interposer 220 including the solder resists 251 and 252 was about 0.50 mm, and the thickness of each of the solder resists 251 and 252 was about 0.015 mm. The outer shape of the printed circuit board 300 was 22.0 mm in length for the side 10 and the side 20, and 15.8 mm in length for the side 30 and the side 40, respectively. The thickness of the printed circuit board 300 including the solder resists 351 and 352 was about 0.37 mm, and the thickness of each of the solder resists 351 and 352 was about 0.016 mm.

The solder joints 610 were arranged in a staggered pattern with a pitch of 0.40 mm. The solder joints 620 were arranged in a staggered pattern with a pitch of 0.60 mm around the outer periphery of the semiconductor element 210. With the solder joints 610 and 620 formed, the height from the surface of the solder resist 151 of the printed circuit board 100 to the solder resist 352 of the printed circuit board 300 was about 0.90 mm.

In the three-dimensional mounting structure 500 described above, the resin 400 was applied to the sides 1, 2, 3, and 4 of the interposer 220 and the sides 10, 20, 30, and 40 of the printed circuit board 300. When the resin 400 was applied, the resin 400 was applied while being discharged from a nozzle, which was attached to a dispenser (not illustrated) and being moved.

Then, the three-dimensional mounting structure 500 to which the resin 400 was applied was placed in an oven (not illustrated) and heated to cure the resin 400 to form the reinforcing resin portion 410 made of the cured resin 400. The curing conditions by the oven were set at a temperature of 125° C. and a time of 30 minutes.

The reinforcing resin portion 410 thus formed had a length of about 15.00 mm, a width of about 1.60 mm, and a height of about 1.20 mm. That is, in the four side portions 511, 512, 513, and 514 of the mounting structure 510 at which the reinforcing resin portion 410 was formed, the length of the reinforcing resin portion 410 is shorter than the sides 1, 2, 3, and 4 of the interposer 220. The side surfaces 1a, 1b, 1c, and 1d of the interposer 220 are exposed from both ends of the reinforcing resin portion 410.

By forming the reinforcing resin portion 410 as described above, the reliability of the solder joints in the three-dimensional mounting structure 500 was able to be improved in Example 1.

### Example 2

Example 2 corresponding to the first embodiment and the sixth embodiment will be described below.

The sizes of the respective portions of the three-dimensional mounting structure 500 were as follows. The outer shape of the printed circuit board 300 was 21.45 mm in length for the side 10 and the side 20, and 15.40 mm in length for the side 30 and the side 40. The thickness of the printed circuit board 300 including the solder resists 351 and 352 was about 0.37 mm, and the thickness of each of the solder resists 351 and 352 was about 0.016 mm. Among the outermost solder joints 610, the distance between the solder joints 610 at both ends near the side 511 and side 512 of the mounting structure 510 is about 14.9 mm. Among the outermost solder joints 620, the distance between the ends of the solder joints 620 at both ends near the side 511 and side 512 was about 15.9 mm.

The reinforcing resin portion 410 was formed at the side portion 511 including the side 1 of the interposer 220 and the side 10 of the printed circuit board 300, and at the side portion 512 including the side 2 of the interposer 220 and the side 20 of the printed circuit board 300. The reinforcing resin portion 410 had a length of about 15.00 mm, a width of about 1.60 mm, and a height of about 1.20 mm.

Other points such as the length of the side of the interposer 220 and the height from the surface of the solder resist 151 of the printed circuit board 100 to the solder resist 352 of the printed circuit board 300, and the like were the same as in Example 1.

In the two side portions 511 and 512 of the mounting structure 510 at which the reinforcing resin portion 410 was formed, the length of the reinforcing resin portion 410 is shorter than the sides 1 and 2 of the interposer 220. The sides 1a and 2a of the interposer 220 were exposed from both ends of the reinforcing resin portion 410. In addition, the solder joints 610 were hidden from the reinforcing resin portion 410 so as not to be seen, and the solder joints 620 were exposed from the reinforcing resin portion 410 at each of both ends, with one solder joint 620 exposed at each end.

By forming the reinforcing resin portion 410 as described above, the reliability of the solder joints in the three-dimensional mounting structure 500 was able to be improved also in Example 2.

Next, in the three-dimensional mounting structure 500, the relationship between the length of the resin 400 applied to the side portion 511 including the side 1 and the side 10 and the side portion 512 including the side 2 and the side 20 of the mounting structure 510 and the stress applied to the solder joints 610 and 620 was simulated. Further, the relationship between the length of the resin 400 applied to the side portions 511 and 512 of the mounting structure 510 and the reliability of the solder joints was also simulated. Note that, in the simulation, the size of each portion of the three-dimensional mounting structure 500 was set in the same manner as in Example 2 except for the length of the resin 400 to be changed. In the simulation, the applied length of the resin 400 was lengthened from the center of the long side of the printed circuit board 300 on the sides 10 and 20 toward both ends of the sides 10 and 20, and the change in the stress applied to the solder joints 610 and 620 at that time and the reliability of the solder joints were confirmed.

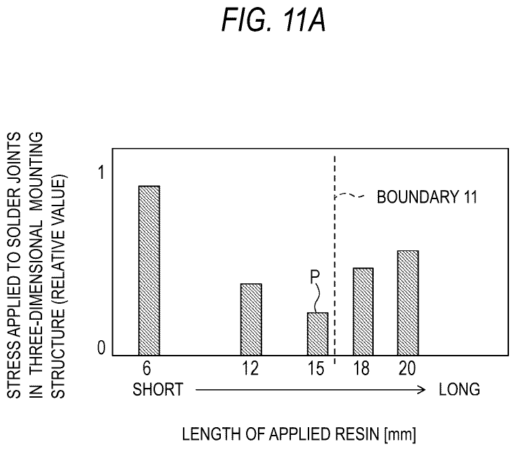

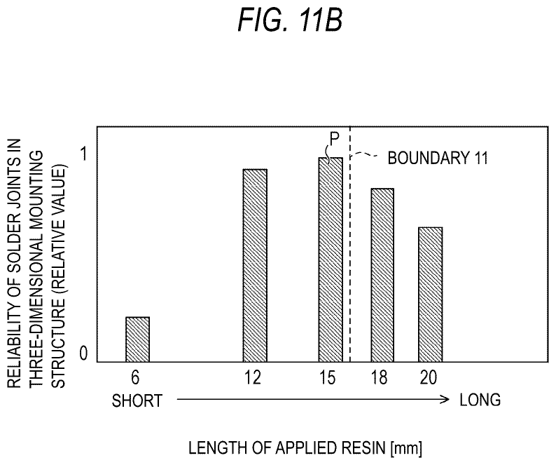

FIG. 11A is a graph showing the results of the simulation of the relationship between the length of the resin 400 applied to the side portions 511 and 512 of the mounting structure 510 and the stress applied to the solder joints 610 and 620 in the three-dimensional mounting structure 500.

By applying the resin 400 to form the reinforcing resin portion 410, the thermal deformation of the interposer 220 and the printed circuit board 300 was suppressed. Therefore, the stress applied to the solder joints 610 and 620 was reduced. However, if the length of the resin 400 was made longer and the length of the resin 400 was made longer than the sides 1 and 2 of the interposer 220, the interposer 220 was greatly affected by the thermal deformation of the printed circuit board 300. As a result, the stress applied to the solder joints 610 and 620 was gradually increased as illustrated on the right side of the boundary 11 in FIG. 11A. The boundary 11 was where the length of the resin 400 to be applied is equal to the length of the sides 1 and 2 of the interposer 220.

FIG. 11B is a graph showing the results of the simulation of the relationship between the length of the resin 400 to be applied to the sides 511 and 512 of the mounting structure 510 and the reliability of the solder joints in the three-dimensional mounting structure 500.

When the resin 400 was applied longer than the boundary 11, the reliability of the solder joints in the three-dimensional mounting structure 500 decreased as shown in FIG. 11B corresponding to an increase in the stress applied to the solder joints 610 and 620 as shown in FIG. 11A. Therefore, as shown in FIG. 11A and FIG. 11B, the length of the resin 400 constituting the reinforcing resin portion 410 is preferably set to an optimum length P within a range not exceeding the boundary 11. In the three-dimensional mounting structure in which the above simulation was performed, the optimum length P was about 15 mm, and the solder joints 620 at both ends were exposed from the resin 400 with one solder joint 620 exposed at each end.

### Example 3

Example 3 corresponding to the second embodiment and the sixth embodiment will be described below.

The sizes of the respective portions of the three-dimensional mounting structure 500 were as follows. The outer shape of the interposer 220 was 16.40 mm in length for the side 1 and the side 2, and 15.20 mm in length for the side 3 and the side 4, respectively. The thickness of the interposer 220 including the solder resists 251 and 252 was about 0.50 mm, and the thickness of each of the solder resists 251 and 252 was about 0.015 mm. The semiconductor element 210 was mounted on the main surface 231 of the insulating substrate 230. The outer shape of the printed circuit board 300 was 21.45 mm in length for the side 10 and the side 20, and 15.40 mm in length for the side 30 and side 40, respectively. The thickness of the printed circuit board 300 including the solder resists 351 and 352 was about 0.37 mm, and the thickness of each of the solder resists 351 and 352 was about 0.016 mm.

The solder joints 610 were arranged in a staggered pattern with a pitch of 0.40 mm. The solder joints 620 were arranged in a staggered pattern with a pitch of 0.42 mm around the outer periphery of the semiconductor element 210. The distance between the center position of the solder joint 610a and the end of the interposer 220 is 0.53 mm. The distance between the center position of the solder joint 620a and the end of the interposer 220 was 0.40 mm. The solder joint 610 was 0.30 mm in diameter. The solder joint 620 was 0.26 mm in diameter. At this time, the distance between the outermost peripheral position of the solder joint 610a and the end of the interposer 220 was 0.40 mm, and was equal to the distance between the center position of the solder joint 620a and the end of the interposer 220. With the solder joints 610 and 620 formed, the height from the main surface 131 of the printed circuit board 100 to the main surface 332 of the printed circuit board 300 was about 0.90 mm.

In the three-dimensional mounting structure 500, the resin 400 was applied to the sides 1 and 2 of the interposer 220 and the sides 10 and 20 of the printed circuit board 300. When the resin 400 was applied, the resin 400 was applied while being discharged from a nozzle, which was attached to a dispenser (not illustrated) and being moved.

Then, the three-dimensional mounting structure 500 to which the resin was applied was placed in an oven (not illustrated) and heated to cure the resin 400 to form the reinforcing resin portion 410 made of the cured resin 400. The curing condition by the oven was set at a temperature of 125° C. and a time of 30 minutes.

The reinforcing resin portion 410 thus formed was about 15.00 mm in length, about 1.60 mm in width, and about 1.20 mm in height.

### Other Embodiments

The embodiments and examples described above are only examples, which are illustrative of some embodiments to which the present disclosure may be applicable. That is, the present disclosure is not limited to the embodiments and the examples described above, and may be modified or transformed as appropriate without departing from the intent of the present disclosure.

In the above-described embodiments, although the cases in which the plurality of lands 342 are provided on the main surface 332 of the insulating substrate 330 of the printed circuit board 300 are explained, the plurality of lands may also be provided on the main surface 331 of the insulating substrate 330. In this case, a printed circuit board, a semiconductor device, an electronic component, or the like may be further mounted on the printed circuit board 300 by solder joints for joining the plurality of lands provided on the main surface 331.

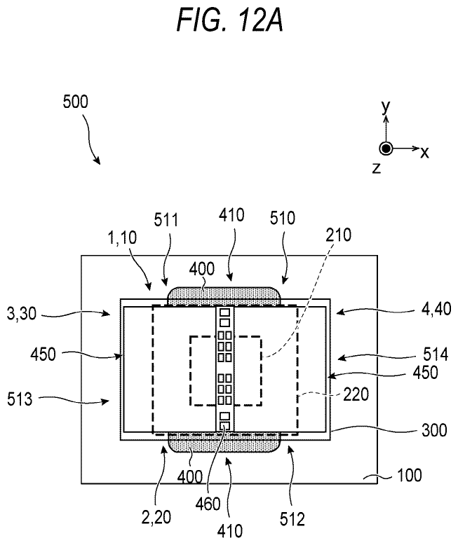

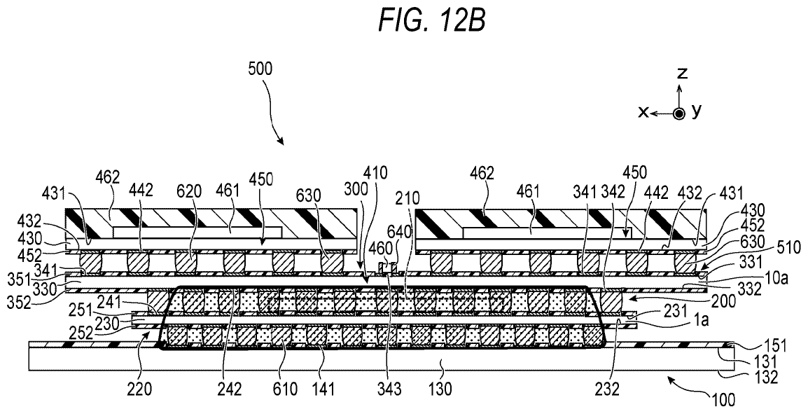

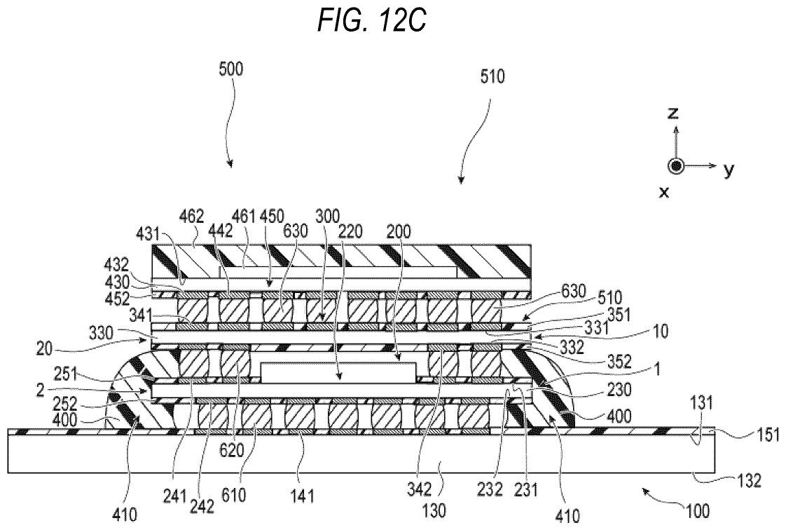

A three-dimensional mounting structure 500 according to another embodiment in which a printed circuit board or the like is further mounted on the printed circuit board 300 will be described with reference to FIG. 12A to FIG. 12C. FIG. 12A is a top view illustrating the three-dimensional mounting structure 500 according to another embodiment. FIG. 12B is a side view illustrating the three-dimensional mounting structure 500 according to another embodiment viewed from the y-axis direction. FIG. 12C is a cross-sectional view illustrating the three-dimensional mounting structure 500 according to another embodiment viewed from the x-axis direction. Note that the same components as those in the first to sixth embodiments will be labeled with the same reference numerals and the detailed description thereof will be omitted or simplified. As illustrated in FIG. 12A to FIG. 12C, in the present embodiment, for example, a plurality of printed circuit boards 450 and a plurality of electronic components 460 are mounted on the main surface 331 of the insulating substrate 330 of the printed circuit board 300.

A plurality of lands 341 and a plurality of lands 343 are arranged on the main surface 331 of the insulating substrate 330 of the printed circuit board 300. The lands 341 and 343 are terminals formed of a metal material having conductivity, for example, copper or gold. A solder resist 351 is provided on the main surface 331 of the insulating substrate 330. Each of the plurality of lands 341 and each of the plurality of lands 343 is exposed by an opening formed in the solder resist 351. The lands 341 and 343 may be either SMD or NSMD lands.

The plurality of printed circuit boards 450 are boards on which semiconductor elements 461 are mounted in a semiconductor device such as a memory, or the like, for example, and the semiconductor elements 461 and other components are mounted on the printed circuit boards 450 (by die bonding) to constitute a semiconductor device. The printed circuit board 450 has an insulating board 430. A plurality of lands 442 are arranged on the main surface 432 of the insulating board 430. A solder resist 452 is provided on the main surface 432 of the insulating board 430. Each of the plurality of lands 442 is exposed by an opening formed in the solder resist 452. The plurality of electronic components 460 are chip components such as capacitors and resistors, and the like, for example.

On the main surface 431 opposite to the main surface 432 of the insulating substrate 430, a semiconductor element 461 such as a memory, or the like, for example, is mounted on the printed circuit board 450. A sealing resin 462 is formed on the main surface 431 including the semiconductor element 461 to seal the semiconductor element 461. The semiconductor device includes at least the semiconductor element 461, and further includes the printed circuit board 450 and the sealing resin 462 as required.

The plurality of lands 341 of the printed circuit board 300 and the plurality of lands 442 of the printed circuit board 450 are joined by solder joints 630. Thus, the plurality of printed circuit boards 450 are arranged on the side opposite to the side on which the interposer 220 is arranged with respect to the printed circuit board 300 and joined to the printed circuit board 300 by the plurality of solder joints 630. The plurality of lands 343 of the printed circuit board 300 and the electronic component 460 are joined by the solder joints 640. The solder forming the solder joints 630 and 640 is, for example, a solder ball.

Thus, the semiconductor device including the semiconductor element 461, the printed circuit board 450, and the sealing resin 462 is arranged on the side opposite to the side on which the interposer 220 is arranged with respect to the printed circuit board 300. For example, a first semiconductor device including one printed circuit board 450 and at least one semiconductor element 461, and a second semiconductor device including another printed circuit board 450 and at least one semiconductor element 461 are arranged side by side in the x-axis direction. Therefore, it is preferable that the x-axis direction in which the plurality of semiconductor devices are arranged is in the long side direction of the printed circuit board 300. Also in the printed circuit board 300, it is effective to provide a reinforcing resin portion 410 at the longer side than the shorter side. Therefore, it is preferable to arrange the reinforcing resin portion 410 at the side portion 511 and the side portion 512 along the x-axis direction in which the plurality of semiconductor devices are arranged. Thus, the distortion of the printed circuit board 300 caused by each of the plurality of semiconductor devices can be suppressed by the reinforcing resin portion 410 arranged at the side portion 511 and the side portion 512. In addition to the side portion 511 and the side portion 512, the reinforcing resin portion 410 may also be arranged at the side portion 513 and the side portion 514 as illustrated in FIG. 4C and FIG. 9A. Note that, when the plurality of semiconductor devices are arranged in the x-axis direction, the reinforcing resin portion 410 may be provided only at the side portion 513 and the side portion 514 along the y-axis direction, but the effect of the reinforcement is reduced compared with the configuration of FIG. 12A.

The plurality of printed circuit boards 450 and the plurality of electronic components 460 may be mounted on the printed circuit board 300 as described above. In the present embodiment, as in the first to sixth embodiments described above, a configuration including the reinforcing resin portion 410 adhering to the printed circuit board 100, the interposer 220, and the printed circuit board 300 can be adopted. In this case, the reinforcing resin portion 410 is separated from the solder joints 630 and 640 and the plurality of printed circuit boards 450.

According to the present disclosure, the reliability of the solder joints in the module can be improved.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-219758, filed Dec. 26, 2023, and Japanese Patent Application No. 2024-070731, filed Apr. 24, 2024, which are hereby incorporated by reference herein in their entirety.

What is claimed is:

1. A module comprising:
a first printed wiring board;
a second printed wiring board arranged on a main surface of the first printed wiring board and joined to the first printed wiring board by a plurality of first solder joints;
a third printed wiring board arranged on a side opposite to a side on which the first printed wiring board is arranged with respect to the second printed wiring board and joined to the second printed wiring board by a plurality of second solder joints;
a first reinforcing resin portion; and
a second reinforcing resin portion,
wherein the second printed wiring board has a first side surface and a second side surface opposing each other in a first direction, and has a third surface and a fourth side surface opposing each other in a second direction that intersects the first direction,
wherein the first reinforcing resin portion adheres to the main surface of the first printed wiring board, the first side surface of the second printed wiring board, and the third printed wiring board, and is away from at least one end of both ends of the first side surface of the second printed wiring board in the second direction, and
wherein the second reinforcing resin portion adheres to the main surface of the first printed wiring board, the second side surface of the second printed wiring board, and the third printed wiring board, and is away from at least one end of both ends of the second side surface of the second printed wiring board in the second direction.

2. The module according to claim 1, wherein the one end of the first side surface is closer to the third side surface than to the fourth side, and the one end of the second side is closer to the fourth side surface than to the third side surface.

3. The module according to claim 1,
wherein the first reinforcing resin portion is away from another end of the both ends of the first side surface of the second printed wiring board in the second direction, and
wherein the second reinforcing resin portion is away from another end of the both ends of the second side surface of the second printed wiring board in the second direction.

4. The module according to claim 1,
wherein the first reinforcing resin portion is separated from a solder joint closest to the one end of the first side surface among the plurality of second solder joints, and
wherein the second reinforcing resin portion is separated from a solder joint closest to the one end of the second side surface among the plurality of second solder joints.

5. The module according to claim 4,
wherein the first reinforcing resin portion is separated from a solder joint closest to another end of the first side surface among the plurality of second solder joints, and
wherein the second reinforcing resin portion is separated from a solder joint closest to another end of the second side surface among the plurality of second solder joints.

6. The module according to claim 5, wherein a distance between the solder joint closest to the one end of the first side surface among the plurality of second solder joints and the solder joint closest to the another end of the first side surface among the plurality of second solder joints is greater than a distance between a solder joint closest to the one end of the first side surface among the plurality of first solder joints and a solder joint closest to the another end of the first side surface among the plurality of first solder joints.

7. The module according to claim 1,
wherein the first reinforcing resin portion is separated from a solder joint closest to the first reinforcing resin portion among the plurality of second solder joints, and
wherein the second reinforcing resin portion is separated from a solder joint closest to the second reinforcing resin portion among the plurality of second solder joints.

8. The module according to claim 1,
wherein the first reinforcing resin portion adheres to a solder joint closest to the first reinforcing resin portion among the plurality of second solder joints, and
wherein the second reinforcing resin portion adheres to a solder joint closest to the second reinforcing resin portion among the plurality of second solder joints.

9. The module according to claim 1,
wherein no resin portion made of the same material as the first reinforcing resin portion adheres to the third side surface, and
wherein no resin portion made of the same material as the second reinforcing resin portion adheres to the fourth side surface.

10. The module according to claim 1, comprising:
a third reinforcing resin portion; and
a fourth reinforcing resin portion,
wherein the third reinforcing resin portion adheres to the main surface of the first printed wiring board, the third side surface of the second printed wiring board, and the third printed wiring board, and is away from at least one end of both ends of the third side surface of the second printed wiring board in the second direction, and
wherein the fourth reinforcing resin portion adheres to the main surface of the first printed wiring board, the fourth side surface of the second printed wiring board, and the third printed wiring board, and is away from at least one end of both ends of the fourth side surface of the second printed wiring board in the second direction.

11. A module comprising:
a first printed wiring board;
a second printed wiring board arranged on a main surface of the first printed wiring board and joined to the first printed wiring board by a plurality of first solder joints;
a third printed wiring board arranged on a side opposite to a side on which the first printed wiring board is arranged with respect to the second printed wiring board and joined to the second printed wiring board by a plurality of second solder joints;
a first reinforcing resin portion; and
a second reinforcing resin portion,
wherein the second printed wiring board has a first side surface and a second side surface opposing each other in a first direction, and has a third side surface and a fourth side surface opposing each other in a second direction that intersects the first direction, and
wherein the first reinforcing resin portion adheres to the main surface of the first printed wiring board, the first side surface of the second printed wiring board, and the third printed wiring board, is separated from a solder joint closest to the first reinforcing resin portion among one joint group of the plurality of first solder joints and the plurality of second solder joints, and adheres to a solder joint closest to the first reinforcing resin portion among another joint group of the plurality of first solder joints and the plurality of second solder joints.

12. The module according to claim 11, wherein the second reinforcing resin portion adheres to the main surface of the first printed wiring board, the second side surface of the second printed wiring board, and the third printed wiring board, is separated from a solder joint closest to the second reinforcing resin portion among one joint group of the plurality of first solder joints and the plurality of second solder joints, and adheres to a solder joint closest to the second reinforcing resin portion among another joint group of the plurality of first solder joints and the plurality of second solder joints.

13. The module according to claim 11,
wherein the one joint group is the plurality of first solder joints, and
wherein the another joint group is the plurality of second solder joints.

14. The module according to claim 13, wherein a distance between the solder joint closest to the first reinforcing resin portion among the one joint group and the first side surface is longer than a distance between the solder joint closest to the first reinforcing resin portion among the another joint group and the first side surface.

15. The module according to claim 11,
wherein a solder portion is provided between the first printed wiring board and the second printed wiring board, which is not joined to one of the first printed wiring board and the second printed wiring board, and
wherein the first reinforcing resin portion adheres to the solder portion.

16. The module according to claim 11,
wherein the second printed wiring board has a step formed outside the second solder joint, and
wherein the first reinforcing resin portion is formed over the step.

17. The module according to claim 16,
wherein the second printed wiring board includes a substrate and a solder resist formed on the substrate, and
wherein the step is formed in the substrate.

18. The module according to claim 16,
wherein the second printed wiring board includes a substrate and a solder resist formed on the substrate, and
wherein the step is an opening formed in the solder resist.

19. The module according to claim 11, wherein the first reinforcing resin portion faces a plurality of third solder joints among the plurality of first solder joints and a plurality of fourth solder joints among the plurality of second solder joints.

20. The module according to claim 1, wherein the first reinforcing resin portion and the second reinforcing resin portion includes a portion positioned between the first printed wiring board and the second printed wiring board and a portion positioned between the second printed wiring board and the third printed wiring board in a third direction perpendicular to the main surface of the first printed wiring board.

21. The module according to claim 1, comprising a semiconductor element arranged between the second printed wiring board and the third printed wiring board,
wherein the plurality of the second solder joints are arranged around the semiconductor element, and
wherein, in the first direction, the semiconductor element is provided between the first reinforcing resin portion and the second reinforcing resin portion.

22. The module according to claim 21, wherein, in the second direction, the second reinforcing resin portion is longer than the semiconductor element.

23. The module according to claim 21, wherein a sum of the number of the second solder joints positioned between the semiconductor element and the first side surface in the first direction and the number of the second solder joints positioned between the semiconductor element and the second side surface in the first direction is less than a sum of the number of the second solder joints positioned between the semiconductor element and the third side surface in the second direction and the number of the second solder joints positioned between the semiconductor element and the fourth side surface in the second direction.

24. The module according to claim 1, wherein a thickness of the third printed wiring board is less than a thickness of the second printed wiring board.

25. The module according to claim 1, wherein the third printed wiring board has a fifth surface and a sixth side surface opposing each other in the first direction, and has a seventh side surface and an eighth side surface opposing each other in the second direction, and
wherein the first reinforcing resin portion adheres to the fifth side surface of the third printed wiring board, and
wherein the second reinforcing resin portion adheres to the sixth side surface of the third printed wiring board.

26. The module according to claim 1, wherein the first side surface and the second side surface of the second printed wiring board are positioned between the first printed wiring board and the third printed wiring board in a third direction perpendicular to the main surface of the first printed wiring board.

27. The module according to claim 1, comprising a fourth printed wiring board arranged on a side opposite to a side on which the second printed wiring board is arranged with respect to the third printed wiring board and joined to the third printed wiring board by a plurality of third solder joints, and
wherein the first reinforcing resin portion and the second reinforcing resin portion are separated from the third solder joints and the fourth printed wiring board.

28. The module according to claim 25,
wherein a distance between the seventh side surface and the eighth side surface is greater than a distance between the fifth side surface and the sixth side surface, and
wherein the distance between the seventh side surface and the eighth side surface is greater than a distance between the third side surface and the fourth side surface.

29. The module according to claim 1, comprising:
a first semiconductor device arranged on a side opposite to a side on which the second printed wiring board is arranged with respect to the third printed wiring board; and
a second semiconductor device arranged on a side opposite to a side on which the second printed wiring board is arranged with respect to the third printed wiring board,
wherein the first semiconductor device and the second semiconductor device are arranged side by side in the second direction.

30. Electronic equipment comprising:
a housing;
a first module arranged inside the housing, and
a second module arranged inside the housing,
wherein the first module and the second module are electrically connected, and
wherein the second module is the module according to claim 1.

31. Electronic equipment comprising:
a housing;
a first module arranged inside the housing, and
a second module arranged inside the housing,
wherein the first module and the second module are electrically connected,
wherein the second module is the module according to claim 11, and
wherein the first module and the second module are electrically connected by a flexible wiring.

32. The electronic equipment according to claim 30, wherein the first module includes an image sensor.
